(19) United States
(12) Patent Application Publication
(10) Pub. No.: US 2026/0282902 A1
(43) Pub. Date: Sep. 17, 2026

(54) POWER ELECTRONICS COMPONENT WITH COOLING AND A POWER CONVERTER

(71) Applicant: TRUMPF Hüttinger GmbH + Co. KG, Freiburg (DE)

(72) Inventors: Guido Dieter Hodapp, Emmendingen (DE); Thilo Vethake, Roosevelt, NJ (US); Aguiar Wagner, Jackson, NJ (US); Vajpey Divya, Somerset, NJ (US); Craig Denham, Millbury, MA (US); Reza Razavi, Monrovia, CA (US)

(21) Appl. No.: 19/672,799

(22) Filed: May 11, 2026

Related U.S. Application Data
(63) Continuation of application No. PCT/EP2024/082605, filed on Nov. 15, 2024.

(30) Foreign Application Priority Data
Nov. 15, 2023 (DE) 10 2023 131 878.0

(51) Int. Cl. H10W 40/20; H10W 40/00

(52) U.S. Cl. CPC H10W 40/233; H10W 40/037; H10W 40/235

(57) ABSTRACT

A power electronics component, including a first substrate with an upper and lower metallization layer and a semiconductor assembly mounted on the first substrate which has a connection to a first region of the upper metallization layer of the first substrate facing the semiconductor assembly. The power electronics component further includes a first heat sink, a first side of which faces the first substrate and is thermally connected to the lower metallization layer of the first substrate, which faces away from the semiconductor assembly. The power electronics component includes an additional substrate having an upper and lower metallization layer, the additional substrate being attached to a second side of the first heat sink opposite the first side, and the second side of the first heat sink being connected to the upper metallization layer of the additional substrate facing -the first heat sink.

### CROSS REFERENCE TO RELATED APPLICATIONS

This application is a continuation of International Application No. PCT/EP2024/082605 (WO 2025/104318 A1), filed on Nov. 15, 2024, and claims benefit to German Patent Application No. DE 10 2023 131 878.0, filed on Nov. 15, 2023. The aforementioned applications are hereby incorporated by reference herein.

### FIELD

The invention relates to a power electronics component with cooling, a method for joining a power electronics component, and an electrical power converter for an industrial process assembly.

### BACKGROUND

There are special challenges when it comes to cooling, especially in the field of electrical power conversion for specific high-power and instability-prone industrial processes, such as plasma excitation, plasma coating processes, gas laser excitation, particle accelerators, charging and discharging systems for large batteries, such as flow batteries, melting of solids, heating and/or gasifying of liquid substances through, for example, microwave energy or induction heating, or plasma burners. This can be a process for generating radiation, e.g., microwave radiation, X-rays. or particle accelerators. Common to all these processes is that they are designed to generate and accelerate charged atomic or subatomic particles in a gas and/or plasma environment or liquid. Another feature common to all of these processes is that they have a high power consumption which is in the range of 1 kW or more, in particular 10 kW or more, preferably 100 kW or more. Thus, frequencies ≥ 20 kHz, preferably ≥ 200 kHz, and in particular ≥ 2 MHz, are generated for the named power range, either internally or for external applications. Many of these processes also have a very high requirement for the stability in the providing of power because the processes are highly complex, such as semiconductor production using plasma processes and/or heating by electromagnetic fields. Typically, power from a mains frequency, which is in the range of approximately 50 Hz to 60 Hz, is converted to different frequencies which can fall within the aforementioned range. Conversion to a direct current power, also called DC power, is also conceivable. Even when converting to direct current power, the power signal is often internally generated at a frequency in the aforementioned range, which is then rectified again according to the requirements for voltage, current, and power. Converting electrical power to other frequencies requires a variety of electronic members and assemblies, especially power semiconductor structural elements such as, for example, transistors or diodes, particularly PIN diodes, e.g., for switching high frequency power between different paths, or a combination of transistor and diode designed for currents ≥ 10 A and voltages ≥ 400 V. These electronic members and assemblies generate waste heat during operation. The waste heat often arises over a very limited area of just a few mm², e.g., ≤ 8 mm². It is a particular challenge to dissipate this waste heat to protect the members and/or assemblies from a destruction due to overheating. Often, very large and material-intensive heat sinks are used for this purpose, the production of which is very expensive.

In conventional solutions, the heat is dissipated by cooling using a cooling plate. When cooling with such a conventional cooling plate, the heat transfer from the electrical structural element, which can have a copper layer, to the cooling medium is achieved by applying a material, such as thermally conducting paste, to the thermal interface, whereby the heat that arises is dissipated. Thus, such thermal interface material proves to be disadvantageous. Firstly, it constitutes another heat transfer with thermal resistance, and secondly, it is subject to wear, which gradually degrades the effectiveness thereof during operation. The surface area of the cooling plate is also increased, or the number and performance of the structural elements are reduced, to dissipate a larger amount of heat. Both options prove to be insufficient. Since the installation space in the housing of such a power supply is limited, the cooling surface cannot be expanded indefinitely. Reducing the performance of individual structural elements is also not a viable solution. Overall, inadequate cooling of the electrical structural elements results in costs.

One particularly challenging field is a process for plasma excitation, especially plasma processing, for example such as coating, e.g., PVD, CVD, or etching. Such processes are used in the manufacturing of semiconductors such as microprocessor components and/or memory chips. Here, the requirements for reliability, durability, and process repeatability are particularly high. At the same time, the performance is also required to be very high. Furthermore, the required output modulations, e.g., in modern electrical power converters with a high frequency amplifier assembly or pulsed high voltage supply with pulse shaping, have steadily increased recently. One requirement for high frequency amplifier assemblies can be, for example, the ability to be pulsed at several different power levels, which is called multi-level pulsing (MLP). Another requirement for high frequency amplifier assemblies can be, for example, the ability to be frequency adjustable, and thus to react quickly to load changes, which is called Auto Frequency Tuning (AFT). Another requirement can be, for example, the ability to provide a pulsed DC voltage that is very high, e.g., greater than or equal to 2 kV, in particular greater than or equal to 7 kV, with pulse frequencies greater than or equal to 1 kHz, in particular greater than or equal to 10 kHz, most preferably greater than or equal to 200 kHz. With all these requirements, the demands on power semiconductor structural elements installed in the high frequency amplifier assembly and used to generate high frequency power also increase. In particular, the requirements for these structural elements to convert into heat power that cannot be delivered to the load in certain states are also increasing. These losses, which are converted into heat, can be ≥ 500 W in some applications, and in particular ≥ 1 kW. This heat must be dissipated from the power semiconductor structural elements, since otherwise they will be destroyed by overheating.

### SUMMARY

In an embodiment, the present disclosure provides a power electronics component, comprising an electrically insulating first substrate which has an upper surface, a lower surface an upper surface metallization layer on the upper surface, and a lower surface metallization layer on the lower surface, and a semiconductor assembly mounted on the first electrically insulating substrate which has at least one first connection thermally and electrically connected to at least one first region of the upper surface metallization layer of the first electrically insulating substrate facing the semiconductor assembly. The power electronics component further comprises a first heat sink, a first side of the first heat sink facing the first electrically insulating substrate being thermally connected to the lower surface metallization layer of the first electrically insulating substrate, the lower surface metallization layer of the first electrically insulating substrate facing away from the semiconductor assembly. The power electronics component further comprises an additional electrically insulating substrate having an upper surface, a lower surface, an upper surface metallization layer on the upper surface of the additional electrically insulating substrate, and a lower surface metallization layer on the lower surface of the additional electrically insulating substrate, the additional electrically insulating substrate being attached to a second side of the first heat sink opposite the first side, and the second side of the first heat sink being thermally connected to the upper surface metallization layer of the additional electrically insulating substrate facing the first heat sink.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows an embodiment of a power electronics component;

FIG. 1a shows an electrical power converter in an industrial process assembly, preferably a plasma process assembly or a heating assembly;

FIG. 2 shows an electronic assembly as part of an embodiment of a power electronics component;

FIG. 3 shows an embodiment of a power electronics component;

FIG. 4 shows an embodiment of an electronic assembly as part of an embodiment of a power electronics component;

FIG. 5 shows connection surfaces of an IGBT;

FIG. 6 shows a means for leading a control connection of a semiconductor structural element laterally out of the power electronics component;

FIG. 7 shows a means for guiding a control connection of a semiconductor structural element laterally out of the power electronics component;

FIG. 8 shows an embodiment of a power electronics component;

FIG. 8a shows an electrical power converter in an industrial process assembly, preferably a plasma process assembly or a heating assembly;

FIG. 9 shows an embodiment of a power electronics component in an oblique view;

FIG. 10 shows an embodiment of a power electronics component;

FIG. 10a shows an electrical power converter in an industrial process assembly, preferably a plasma process assembly or a heating assembly; and

FIG. 11 shows guiding of a control connection of a semiconductor structural element out of the power electronics component.

### DETAILED DESCRIPTION

In an embodiment, the present disclosure provides a power electronics component and a method for joining a power electronics component that enable improved dissipation of the heat generated during the operation of power electronics structural elements. Furthermore, an embodiment of the present disclosure provides an electrical power converter for an industrial process assembly that enables improved dissipation of the heat generated during the operation of power structural elements. In an embodiment, the industrial process assembly is preferably a plasma process assembly or a heating assembly, comprising in particular a high frequency amplifier assembly. This high frequency amplifier assembly includes a previously mentioned power electronics component and is designed to generate high frequency output power, in particular for plasma excitation such as plasma coating processes, preferably for the production of semiconductor structures.

In an aspect, the power electronics component comprises a semiconductor assembly and an electrically insulating first substrate on which the semiconductor assembly is mounted and which has a metallization layer on the upper and lower surfaces thereof, wherein at least one connection of the semiconductor assembly is thermally and electrically connected to at least one region of the metallization layer of the first substrate facing the semiconductor assembly. Furthermore, the power electronics component includes a first heat sink, the first side of which, facing the first substrate, is thermally and electrically connected to the metallization layer of the first substrate facing away from the semiconductor assembly. Furthermore, the power electronics component comprises an electrically insulating additional substrate which has a metallization layer on the upper and lower surfaces thereof, wherein the additional substrate is attached to the second side of the first heat sink opposite the first side and wherein the second side of the first heat sink is thermally, and in particular also electrically, connected to the metallization layer of the additional substrate facing the first heat sink.

In the power electronics component according to this solution, the lower surface of a semiconductor assembly is cooled. For this purpose, the semiconductor assembly is thermally and electrically connected to the metallization of a first substrate facing the semiconductor assembly. A thermal and electrical connection to the first heat sink is formed via the metallization of the first substrate facing away from the semiconductor assembly. The heat generated on the side of the semiconductor assembly can therefore be efficiently transferred via the metallization layers of the first substrate to the first heat sink and there dissipated. The side of the heat sink facing away from the semiconductor assembly is connected to an additional substrate. For this purpose, the first heat sink is thermally, and especially also electrically, connected to the metallization of the additional substrate facing the heat sink. The first heat sink is therefore connected to the first substrate on the upper surface thereof and to the additional substrate on the lower surface thereof. This sandwich arrangement creates a mechanically stable component. Another advantage is that additional assemblies and structural elements can be placed on the additional substrate, and the heat generated during operation can also be dissipated via the first heat sink. In particular, this would include, for example, control circuits that generate the control signals required for the operation of power structural elements. However, the use of the additional substrate is not limited to control circuits; rather, the additional substrate can be used for any type of structural element and assembly.

In an aspect, a method for joining a power electronics component is disclosed. The method comprises arranging a semiconductor assembly on an electrically insulating first substrate, which has a metallization layer on the upper and lower surfaces thereof, and establishing at least one thermal and electrical connection between at least one connection of the semiconductor assembly and at least one region of the metallization layer of the first substrate facing the semiconductor assembly. Furthermore, the method includes arranging a first heat sink on the first substrate and establishing a thermal and electrical connection between a first side of the first heat sink facing the first substrate and the metallization layer of the first substrate facing away from the semiconductor assembly. Furthermore, the method includes arranging an electrically insulating additional substrate, which has a metallization layer on the upper and lower surfaces thereof, on the second side of the first heat sink opposite the first side, and establishing a thermal and electrical connection between the second side of the first heat sink and the metallization layer of the additional substrate facing the first heat sink.

In an aspect, the power electronics component comprises an electrically insulating first substrate which has a metallization layer on both the upper and lower surfaces thereof, and a semiconductor assembly mounted on the first substrate which has at least one first connection that is thermally and electrically connected to at least one region of the metallization layer of the first substrate facing the semiconductor assembly. Furthermore, the power electronics component comprises an electrically insulating second substrate mounted on the semiconductor assembly, which has a metallization layer on the upper and lower surfaces thereof, wherein the semiconductor assembly has at least one second connection that is thermally and electrically connected to at least one region of the metallization layer of the second substrate facing the semiconductor assembly, a first heat sink that is thermally and electrically connected to the metallization layer of the first substrate facing away from the semiconductor assembly, wherein the first heat sink has at least one first cooling channel through which coolant can flow, and a second heat sink that is thermally, and in particular also electrically, connected to the metallization layer of the second substrate facing away from the semiconductor assembly, wherein the second heat sink has at least one second cooling channel through which coolant can flow.

In an aspect, the power electronics component features a semiconductor assembly that can be cooled on both the upper and lower surfaces thereof. For this purpose, the semiconductor assembly is thermally and electrically connected on the lower surface to the metallization of the first substrate facing the semiconductor assembly, wherein the metallization of the first substrate facing away from the semiconductor assembly is thermally, and in particular also electrically, connected to the first heat sink. This arrangement allows for improved heat dissipation on the lower surface of the semiconductor assembly. The upper surface of the semiconductor assembly is thermally and electrically connected to the metallization of the second substrate facing the semiconductor assembly, wherein the metallization of the second substrate facing away from the semiconductor assembly is thermally, and in particular also electrically, connected to a second heat sink. This also enables efficient heat dissipation on the upper surface of the semiconductor assembly. Heat dissipation is further improved by having both the first heat sink and second heat sink each have at least one cooling channel through which coolant can flow. Thanks to the power electronics component described here, even large amounts of heat generated on the side of the semiconductor assembly can be efficiently dissipated. It is particularly advantageous that the thermal coupling of the heat sinks takes place via the metallizations of the first and second substrates, because improved heat transfer is achieved by coupling the heat sinks via metallization layers. The solution described here provides a compact and mechanically stable component that cools the semiconductor assembly on both sides and provides improved heat dissipation.

In an aspect, a method for joining a power electronics component is disclosed. The method comprises arranging a semiconductor assembly on an electrically insulating first substrate, which has a metallization layer on the upper and lower surfaces thereof, and establishing at least one thermal and electrical connection between at least one first connection of the semiconductor assembly and at least one region of the metallization layer of the first substrate facing the semiconductor assembly. Furthermore, the method comprises arranging an electrically insulating second substrate, which has a metallization layer on the upper and lower surfaces thereof, on the semiconductor assembly and establishing at least one thermal and electrical connection between at least one second connection of the semiconductor assembly and at least one region of the metallization layer of the second substrate facing the semiconductor assembly. Furthermore, the method comprises arranging a first heat sink on the first substrate, wherein the first heat sink has at least one first cooling channel through which coolant can flow, establishing a thermal and electrical connection between the first heat sink and the metallization layer of the first substrate facing away from the semiconductor assembly, arranging a second heat sink on the second substrate, wherein the second heat sink has at least one second cooling channel through which coolant can flow, and establishing a thermal and electrical connection between the second heat sink and the metallization layer of the second substrate facing away from the semiconductor assembly.

To describe the structure of the power electronics component, the present disclosure includes terms such as “on,” “upper surface,” “lower surface” to describe the geometric arrangement of the components of the power electronics component. This information refers to a power electronics component placed on a horizontal surface. The use of these terms is not to be understood as restrictive with regard to the spatial orientation of the power electronics component. Rather, the power electronics component can be used in any spatial orientation. In particular, the power electronics component can be used in any installation position.

In an aspect, the semiconductor assembly comprises one or more semiconductor structural elements.

The semiconductor assembly is preferably arranged in a "bare die layer". The term “bare die layer” here refers to a layer in which one or more semiconductor structural elements are arranged as “bare dies”. The term “bare dies” originates from English usage. The frequently used terms also include: “bare chips”, “die” or “chip” are used synonymously. This refers to integrated electronic structural elements that are not conventionally installed in a plastic or ceramic housing, but are processed further without a housing. They are applied directly to the conductor structure of the substrate and can be electrically connected to surrounding structural elements or conductor structures by means of bonding, in particular by means of chip bonding. Bonding, as used here, refers to the connection of bare dies to other structural elements or conductor structures.

The bare die layer can contain regions where no semiconductor structural elements are located. These regions can be filled with a filler material. This filler material can be designed to improve stability, reduce mechanical stresses and/or improve electrical insulation, for example by increasing air and/or creepage distances.

The term “connection” here refers to any type of connection that the semiconductor assembly can have, for example: collector connection, emitter connection, drain connection, source connection, control connection, test connection. In particular, it can be a power connection, for example: collector connection, emitter connection, drain connection, source connection. Each connection can have a contact surface with which it can be contacted on one of the metallizations. A power connection can have a relatively large area of 2 mm² or more.

An electrical connection refers in particular to a high-quality, low-resistance and low-inductance connection. It should preferably have a contact resistance of 0.2 Ω or less and preferably a contact inductance of 5 nH or less.

A “thermal connection” refers in particular to a high-quality thermal connection with low thermal resistance.

The requirement arises from predictable power dissipation, e.g., in a semiconductor component, such as a transistor, a diode, in particular a PIN diode, e.g., for switching high frequency power between different paths, or of a combination of transistor with diode, and system thermal resistance from bare die to the coolant. The system thermal resistance is calculated as the sum of all thermal resistances. The first important thermal resistance, which cannot be influenced by the cooling assembly, is the thermal resistance between the bare die or chip and the bare die cooling surface. The producer specifies it as RthJ/C (from the English “junction/case”). It depends on the cooling surface of the semiconductor component and, for currently common transistors, is between 0.7 K/W and 0.8 K/W.

As mentioned previously, modern plasma process applications, especially in the manufacturing of semiconductors such as computers or memory chips, place high demands on electrical power converters. These can often only be achieved if the semiconductor component(s) are designed to absorb a significant amount of power loss. This can be, for example, greater than or equal to 1 kW. To achieve this, a thermal resistance of less than or equal to 0.15 K/W measured from bare die or chip to coolant should preferably be achieved. After extensive simulations and tests, it was determined that this can be achieved with the available power electronics component. Further improvements are not excluded and are always welcome.

In an aspect, the first heat sink is at least partially realized in the form of a layered structure made of thermally bonded metal foils, preferably copper foils. Such a production of a monolithic heat sink is disclosed, for example, in DE4315580A1, in which individual metal foils are at least partially structured by means of laser processing and/or stamping and/or produced by means of electroplating processes and then joined together. Such a process will hereinafter be called a 'metal layer bonding process'. Preferably, the first heat sink is produced at least partially using a metal layer bonding process. Preferably, the metal foils are bonded to each other by a bonding process under high pressure and at high temperature.

In an aspect, the heat sink is made of copper. Copper has very good thermal conductivity and electrical conductivity. For example, oxide layers can be formed on the surfaces of copper layers, which are then welded together, wherein the temperature is preferably chosen to be so high that the oxide layers melt, but not the metal foils. This is how the metal foils combine to form a monolithic heat sink. If the metal foils are made of copper, for example, this is also referred to as direct copper bonding, abbreviated DCB.

In an aspect, the metal foils have a thickness of 0.4 mm or less, in particular 0.25 mm or less. This allows for very effective heat dissipation.

In an aspect, the first heat sink has at least one first cooling channel through which coolant can flow, wherein the at least one first cooling channel is realized in the form of at least one recess provided in the metal foils. For example, the structuring or production of the metal foils can be carried out in such a way that, after the layers are joined together, closed channels are created through which a cooling medium can flow.

It is advantageous if the first heat sink is connected to the metallization layer of the first substrate facing away from the semiconductor assembly by at least one of the following: Sintering, pressing, a metal layer joining process, in particular DCB, at least one soldered joint.

In an aspect, the first heat sink is at least partially produced using an additive manufacturing process, preferably using selective laser melting. Such an additive manufacturing process is disclosed, for example, in EP1672690B1 Micro Heat Sink. The now more common term 'additive manufacturing process' is described there using the selective laser melting process. However, the term 'additive manufacturing process' can also include processes other than selective laser melting. An additive manufacturing process is characterized by the fact that the structure is gradually applied from the same material. Thus, the material can be melted during application. Lasers are currently a suitable option for achieving particularly fine structures.

In an aspect, a large number of cooling pins are arranged in the first cooling channel or in a sub-region of the first cooling channel, extending into the first cooling channel. The cooling pins are surrounded by the coolant flowing in the cooling channel. This allows for improved thermal coupling.

It is advantageous if the first cooling element comprises a coolant supply and a coolant discharge, both of which are fluidically connected to the first cooling channel, wherein the first cooling element is designed such that the first cooling element can be detachably attached to a cooling unit comprising a first fluid port and a second fluid port, and that when the first cooling element is attached to the cooling unit, a first fluidic connection can be formed between the coolant supply of the first cooling element and the first fluid port of the cooling unit, as well as a second fluidic connection between the coolant outlet of the first cooling element and the second fluid port of the cooling unit. The cooling unit is configured such that the first heat sink supplies coolant and discharges the coolant again. For example, the first heat sink can be designed in such a way that when attaching the first heat sink to the cooling unit, fluid-tight fluidic connections between the first heat sink and the cooling unit can be formed. For example, the power electronics component can be removed from the cooling unit if required. This allows, for example, a detachable fastening of the power electronics component in the cooling unit. This is particularly advantageous in terms of maintenance and repair.

In an aspect, the first heat sink is a micro heat sink and the semiconductor assembly is an electronic structural element. A micro heat sink is designed to cool a single electronic structural element. This allows for individual cooling that can be adapted to the heat generated by the electronic structural element.

In an aspect, the first substrate is connected in a materially bonded manner to the first heat sink on a first cooling wall, wherein the power electronics component is designed such that, during operation, the coolant is guided through the first cooling channel at a predetermined operating pressure, wherein a distance between the first cooling channel and the first cooling wall is chosen to be so small that the first heat sink, without the first substrate connected thereto in a materially bonded manner, cannot ensure sufficient structural stability and/or tightness at the predetermined operating pressure, and the first substrate and the connection thereof in a materially bonded manner with the first heat sink on the first cooling wall are designed such that the power electronics component can ensure this sufficient structural stability and tightness. A typical specified operating pressure can be, for example, 3 bar or more of overpressure relative to ambient pressure. There are several ways to design the substrate and the materially bonded connection thereof with the heat sink on the cooling wall so that the cooling assembly can ensure sufficient structural stability and tightness. The substrate can, for example, have a certain minimum thickness throughout. For example, the substrate can be designed to be thicker in places where the distance between the cooling channel and the substrate is particularly thin, to ensure stability only in these positions. However, the structural stability of the substrate is only one parameter. The strength of the connection in a materially bonded manner between the substrate and the heat sink is also important. The more stable the substrate can be designed, the thinner it can be.

It is advantageous if the first cooling channel is characterized in that the cross-section thereof has at least in sections a geometric shape for which the width, measured parallel to the first cooling wall, decreases in the direction of the first cooling wall, and wherein the geometric shape of the cross-section at the first cooling wall has a distance to the substrate which is designed such that, at the given operating pressure of the coolant, the first cooling element cannot ensure sufficient structural stability and/or tightness without being connected in a materially bonded manner to the first substrate.

It is advantageous if at least one control connection and at least one first power connection are arranged on the first side of the semiconductor assembly and at least one second power connection is arranged on the second side of the semiconductor assembly. In this embodiment, the first power connection can be electrically contacted from the first side and the second power connection from the second side. This enables large-area electrical contacting of the power connections. Given the high currents flowing through the power connections, this is advantageous. The following discusses some solutions for how the control connection, which typically carries less current compared to the power connections, can be guided out of the power electronics component.

In an aspect, the metallization layer facing the first side of the semiconductor assembly has at least one first metallization region for electrically contacting at least one control connection of the semiconductor assembly and at least one second metallization region for electrically contacting at least one first power connection of the semiconductor assembly, wherein the at least one first metallization region and the at least one second metallization region are electrically separated from each other, and wherein at least one first metallization region is guided to the side of the component and can be electrically contacted from the side of the component. In this embodiment, at least one control connection can be electrically contacted through at least one first metallization region and at least one first power connection through at least one second metallization region. This allows the control connection to be guided to the side of the component.

It is advantageous if the at least one first metallization region and the at least one second metallization region of the metallization layer are separated from each other by means of an etching process. The etching process allows the metallization layer to be divided into different, electrically separated metallization regions.

In an aspect, a contacting structure is provided for electrical contacting the control connection, which is arranged on the metallization facing the first side of the semiconductor assembly, wherein the contacting structure comprises at least one insulating material layer and a conductive layer, and wherein the conductive layer is electrically connected to the control connection and is guided to the side of the component. It is particularly advantageous if the conductive layer, which serves to bring out the control connection, is electrically separated from other metallization regions by means of insulating material layers.

In an aspect, at least one control connection of the semiconductor assembly is electrically contacted via at least one through-connection through the first heat sink, also called a “via”. At least one of the control connections can be contacted via the at least one via from the side facing away from the semiconductor assembly.

In the region of one or both heat sinks, a via insulation can be provided for a via, which protects the through-connection from electrical contact with the heat sink.

In an aspect, the second heat sink is produced at least partially using a metal layer bonding process, in particular a DCB process. It is advantageous if the metallization layers of the second substrate and the metal foils of the second heat sink are bonded in a process. This means that all the metal foils that form the heat sink and the metallization layer of the substrate are bonded to each other in a process.

In an aspect, the first heat sink is produced at least partially using a metal layer bonding process, in particular a DCB process. It is advantageous if the metallization layers of the first substrate and the metal foils of the first heat sink are bonded in a process. This means that all the metal foils that form the heat sink and the metallization layer of the substrate are bonded to each other in a process.

In an aspect, the second heat sink is at least partially realized in the form of a layered structure made of thermally bonded metal foils, preferably copper foils. For example, metal foils can be structured at least partially by means of laser processing and/or stamping and/or manufactured using electroplating processes and then joined together. Preferably, the second heat sink is produced at least partially using a metal layer bonding process. Preferably, the metal foils are bonded to each other by a bonding process under high pressure and at high temperature.

In an aspect, the heat sink is made of copper. Copper has very good thermal conductivity and electrical conductivity. For example, oxide layers can be formed on the surfaces of copper layers, which are then welded together, wherein the temperature is preferably chosen to be so high that the oxide layers melt, but not the metal foils. This is how the metal foils combine to form a monolithic heat sink. If the metal foils are made of copper, for example, this is also referred to as direct copper bonding, abbreviated DCB.

In an aspect, the metal foils have a thickness of 0.4 mm or less, in particular 0.25 mm or less. This allows for very effective heat dissipation.

In an aspect, the second heat sink is connected to the metallization layer of the second substrate facing away from the semiconductor assembly by at least one of the following: Sintering, pressing, a metal layer joining process, in particular DCB, at least one soldered joint.

In an aspect, the first substrate and/or the second substrate is one of the following: ceramic substrate, direct bonded copper (DBC), insulated metal substrate (IMB), active metal brazed (AMB), thick film substrate.

In an aspect, the first substrate is arranged to be substantially parallel to the second substrate. The semiconductor assembly is surrounded at the bottom by the first substrate and at the top by the second substrate, each of which is thermally connected to the associated heat sinks. This allows for efficient heat dissipation to both sides. The symmetrical arrangement of the substrates results in a space-saving design and a favorable geometry with regard to the installation of the component.

In an aspect, the first heat sink and the second heat sink are both micro heat sinks, and the semiconductor assembly is an electronic structural element. In this embodiment, the first and second heat sinks are each designed as micro heat sinks. A micro heat sink is designed to cool a single electronic structural element. In this case, the electronic structural element is cooled by both the first and the second heat sink, both of which are designed as micro heat sinks. The electronic structural element, together with the two micro heat sinks, can, for example, be removed from a larger component and reinserted thereinto, which is advantageous from the point of view of maintenance and repair. This allows for individual cooling that can be adapted to the heat generated by the electronic structural element.

It is advantageous if the component includes a control electronics unit that is arranged on the side of the additional substrate facing away from the first heat sink, wherein at least one connection of the control electronics unit is thermally and electrically connected to at least one region of the metallization layer facing the control electronics unit. Preferably, a control electronics unit that generates the signals required for controlling the semiconductor assembly can be placed on the additional substrate. In this way, the control signals can be generated for the semiconductor assembly located on the first substrate in the immediate spatial environment of the semiconductor assembly. This allows signal interference in the control signals, which can be caused, for example, by the coupling of electromagnetic interference signals, to be reduced or avoided. The at least one via allows, for example, the control signals generated by the control electronics unit to be routed directly to the semiconductor assembly to control power electronics structural elements there. In the region of the heat sink, via insulation can be provided to protect the through-connection from electrical contact with the heat sink.

In an aspect, at least one connection of the control electronics unit is electrically connected to a connection of the semiconductor assembly via at least one via that passes through the first heat sink.

In an aspect, the first heat sink has at least one first cooling channel through which coolant can flow. It is advantageous if the first heat sink is realized in the form of a layered structure made of thermally bonded metal foils, preferably copper foils, and the first cooling channel is realized in the form of at least one recess provided in the metal foils.

In an aspect, the first substrate and/or the additional substrate is one of the following: ceramic substrate, direct bonded copper (DBC), insulated metal substrate (IMB), active metal brazed (AMB), thick film substrate.

Preferably, the first substrate is arranged to be essentially parallel to the additional substrate. By arranging the first substrate on the lower surface of the first heat sink and the second, additional substrate parallel thereto on the upper surface of the heat sink, a compact geometric structure is created in which the heat sink is stabilized by the two substrates. The coolant supply and coolant discharge of the heat sink can, for example, be accessible from the side of the heat sink or, alternatively, be guided through the additional substrate.

The advantages of the present disclosure are also provided by an electrical power converter for an industrial process assembly, preferably a plasma process assembly or a heating assembly, comprising a power electronics component as described above or below. The electrical power converter can be specifically designed to generate high frequency output power. High frequency output power here refers to an output power in the range of 1 kW or more, in particular 10 kW or more, preferably 100 kW or more at frequencies ≥ 20 kHz, preferably ≥ 200 kHz, and in particular ≥ 2 MHz.

As mentioned at the outset, such a power converter is particularly dependent on a very efficient and reliable cooling, which can be achieved particularly well with such a power electronics component.

EP3317966B1 describes an arrangement with a printed circuit board for cooling on a metallic cooling plate. For this purpose, the circuit board has a bottommost layer, wherein the bottommost layer is designed as a metallic layer that serves as a reference ground. However, the heat transfer from the circuit board to the cooling plate is not optimal. The circuit board often does not lie flat on the cooling plate. To counteract the lack of heat transfer due to this disadvantage, heat-conducting paste is used, but this is disadvantageous in the production process and can undergo aging, which can further deteriorate the heat transfer.

In an aspect, the power electronics component comprises two power semiconductor structural elements, in particular transistors, each having a first and a second power connection and a control connection, wherein both power semiconductor structural elements, in particular transistors, are connected in series with one of the power connections thereof, wherein a DC current or DC voltage is connected to the remaining power connections. This can be done directly, for example, or via a filter or an inductor. Furthermore, a control electronics unit can be provided which is connected to the control connections of the power semiconductor structural elements and the control electronics unit is designed to control the power semiconductor structural elements, in particular transistors, in such a way that they can generate high frequency power to switch from a first conducting state to a second conducting state, wherein the conductivity of the two states is different. Such an arrangement can be operated very efficiently, e.g., in Class D, Class E or Class F or Class F⁻¹ operation. Such an operation generates less power loss than, for example, Class A or Class B operation. In combination with the very good cooling provided by the described power electronics component, an even further improved supply to industrial processes can be achieved, for example by allowing them to be operated at higher power. Typical operating classes for generating high frequency power are described, for example, in EP 1 601 098 B1.

In an aspect, the two power semiconductor structural elements, in particular transistors, can each be connected with the first power connection thereof to a common connection point, in particular a ground connection point, wherein the power semiconductor structural elements, in particular transistors, are of a similar design and are arranged on the multilayer printed circuit board. This allows for further improvements in cooling and increased power output.

In an aspect, one of the two power semiconductor structural elements, in particular transistors, can be connected with the first power connection thereof to the other power semiconductor structural element, in particular transistor, with the second power connection thereof at a common connection point, wherein the power semiconductor structural elements, in particular transistors, are of a similar design and are arranged on the multilayer printed circuit board. This allows for further improvements in cooling and increased power output.

In an aspect, a power transformer with a primary winding and a secondary winding can be arranged on the circuit board, wherein the primary winding is connected to the at least one power connection of the power semiconductor structural elements, in particular transistors. The primary winding and the secondary winding of the power transformer can each be designed as planar conductor tracks arranged in different positions on the circuit board. The circuit board can have a thermal connection with the cooling unit. This allows for further improvements in cooling and a further increase in power output.

In an aspect, the thermal connection with the cooling unit can have a thermally conductive compensation layer that is fixedly bonded with the first surface thereof to the first surface of the circuit board. In addition, the thermal connection can alternatively or additionally have a bonding layer which is fixedly bonded with the first surface thereof to the second surface of the heat-conducting compensation layer and fixedly bonded with the second surface thereof to the cooling unit.

The cooling unit can exhibit here a heat-distributing characteristic. It can be designed to be electrically conductive or insulating.

“Fixedly bonded” means that the bonding is firm and durable, such as adhesion, welding, soldering, or pressing, and preferably only separable with high heat and/or mechanical pressure.

In particular, the connection can be established in a materially bonded manner. This prevents air entrapment and ensures good thermal conduction properties.

The thermally conductive compensation layer is suitable for conducting heat from the circuit board towards the cooling unit. It can compensate for unevenness caused, for example, by conductor tracks, windings, or contact pads on the lower surface of the circuit board, and provide a homogeneous and flat plane in the direction of the cooling unit.

The thermally conductive compensation layer can consist of or comprise a prepreg or unreinforced adhesive. The insulating circuit board and the heat distributor can be bonded by heating and pressing together a prepreg inserted therebetween. “Prepreg” is a common material name, which is an abbreviation of “pre-impregnated”. This usually refers to pre-impregnated, mostly planar, flat textile semi-finished products with a thermoplastic or thermosetting matrix, such as unidirectional layers of threads, fabrics, or scrims with threads often arranged at right angles.

Prepregs are cured under temperature and pressure to produce members. For example, they are prefabricated in a web shape, wound on rolls. The term prepreg includes not only unidirectionally reinforced or flat semi-finished products, but also other preforms of basically any shape, which in the broadest sense consist of or comprise a fiber-filled, uncured thermosetting matrix. The matrix is in a partially cross-linked state and is pasty to solid, but can be liquefied again by heating.

Prepregs are machine-processable and are therefore often used in automated processes. They produce consistent and high quality. Advantages are the low undulation and high fiber volume content thereof. Curing at high temperatures enables short cycle times in further processing. Processing requires high investment costs, e.g., for autoclaves, laying robots and refrigerated storage. Such prepregs are generally used to join a plurality of circuit boards together to form a multilayer circuit board. To ensure a secure and long-lasting joining together, the materials to be joined together should have very similar properties regarding the expansion thereof when heated. However, this is not necessarily the case with the circuit board and the heat distributor, in particular if the heat distributor is made of ceramic. This is an argument initially against such a connection. However, ceramics have very good thermal conductivity and at the same time very good electrical insulating properties and also low dielectric losses when insulating high frequency signals of high voltage. Contrary to expectations, tests have shown that even with small dimensions, a secure and long-lasting joining together of materials with different properties can be provided, such as ceramic with FR-4 and/or ceramic with PTFE material. “Small dimensions” means a bonding surface of less than 400 cm² and/or with a maximum length of 20 cm.

The bonding layer can comprise an adhesive based on a resin. It can be thinner than the thermally conductive compensation layer.

The bonding layer can comprise an adhesive film.

Together, the two layers can form a fixed connection with good thermal conduction properties to the cooling unit.

In an aspect, such an electrical power converter will improve the properties of a power supply system that has LDMOS transistors as the elements to be cooled, as disclosed, for example, in DE 10 2013 226 537 A1, EP 3 317 964 B1, EP3 317 965 B1. The load capacity of LDMOS transistors in such power supply systems often reaches the limits thereof because they get too hot, even though neither the maximum voltage rating thereof nor the maximum current rating thereof is reached. This means that with an improvement in cooling as described above and below, such power supply systems can be operated much more reliably.

In an aspect, such an electrical power converter will improve the properties of a power supply system that provides very high voltages at the output thereof, in particular voltages greater than or equal to 1 kV, particularly preferably greater than or equal to 2 kV, and in particular greater than or equal to 4 kV. Particularly preferred is when they are also provided in a pulsed manner, as described for example in EP 4 235 737 A1 as a high-power generator. Since the switching elements described there must switch on even when a voltage is applied to the power connections thereof, these switching operations have particularly high losses. EP 4 235 737 A1 describes a very complex cooling process, which can be improved with the device and/or method described here.

In an aspect, such an electrical power converter will improve the characteristics of a power supply system that includes a coupler unit, in particular a phase-shifting coupler unit, preferably a 90° hybrid coupler, as described, for example, in DE 10 2013 226 537 A1 or WO 2020/025547 A1. Thus, this coupling unit described therein can be used independently of other features as described in DE 10 2013 226 537 A1 or WO 2020/025547 A1. The coupler unit can preferably have a first and a second planar inductance, as also described in DE 10 2013 226 537 A1.

In an aspect, such an electrical power converter will improve the characteristics of a power supply system that uses GaN transistors as the element to be cooled. Such power converters are described, for example, in WO 2010/091696 A1 or WO 2010/091697 A1.

In an aspect, such an electrical power converter will improve the characteristics of a power supply system that uses SiC transistors as the element to be cooled. Such power converters are described, for example, in WO 2020/025547 A1.

The patent publications DE 10 2013 226 537 A1, EP 3 317 964 B1, EP3 317 965 B1, WO 2010/091696 A1, WO 2010/091697 A1, WO 2020/025547 A1 and EP 4 235 737 A1 are incorporated in their entirety by reference herein.

Further advantageous configurations are described in more detail below with reference to a number of exemplary embodiments shown in the drawings, to which the development described here is not limited, however.

In the following description of preferred embodiments, identical reference symbols designate identical or comparable components.

The semiconductor assembly 28 described in the following figures comprises electronic members and assemblies for power applications, in particular power semiconductor structural elements such as transistors or diodes, especially PIN diodes e.g., for switching high frequency power between different paths, or a combination of transistor with diode, which are designed for example for currents ≥ 10 A and voltages ≥ 400 V. These can generate a high amount of waste heat during operation, which must be dissipated. The load capacity of such electronic members and assemblies often reaches its limits because they become too hot, even though neither the maximum voltage rating thereof nor the maximum current rating thereof has been reached.

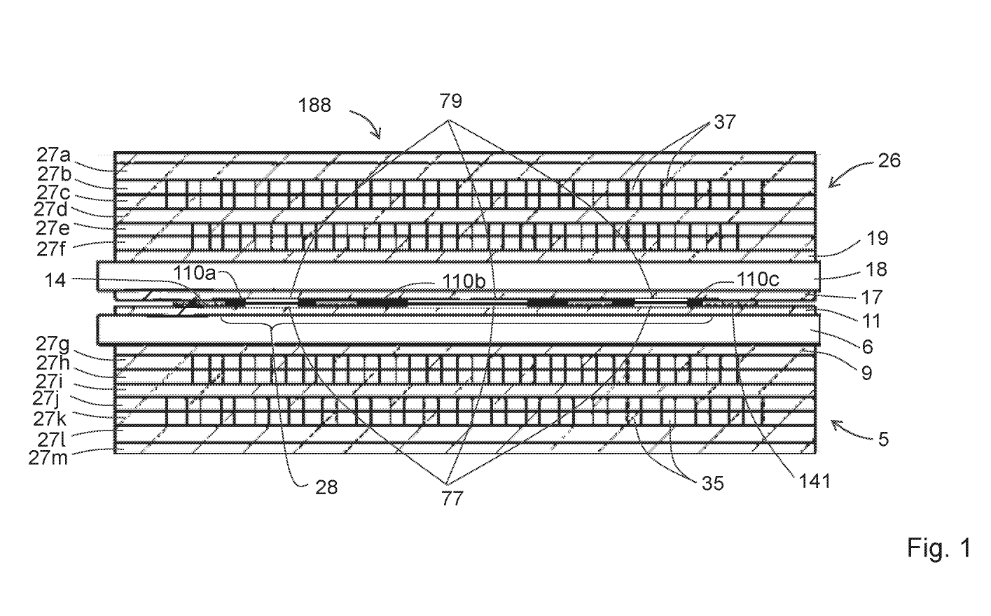

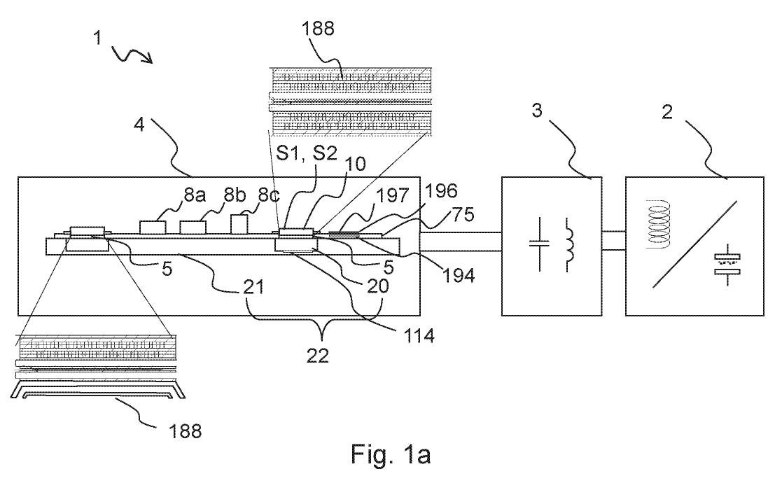

FIG. 1 shows a first power electronics component 188 in which double-sided cooling is provided for the heat dissipation of the structural elements, i.e., cooling from both the upper and lower surfaces of the structural elements. FIG. 1 shows a semiconductor assembly 28 in a bare die layer 14, which can include one or more semiconductor structural elements 110a-c. These semiconductor structural elements 110a-c can represent power semiconductor devices, e.g., transistors and/or diodes for switching and conducting very high power, very high current, and/or very high voltage. The power output can be, for example, 10 kW or more. The voltage can be, for example, 400 V or more, in particular 1 kV or more. The current can be, for example, 10 A or more, in particular 50 A or more. The switching frequency can be, for example, 10 kHz or more, preferably 100 kHz or more, in particular 1 MHz or more.

The semiconductor structural elements are fixedly bonded on the lower surfaces thereof to the conductor structures 11a-c of a metallization 11, which is applied to the upper surface of a first substrate 6. This metallization 11 on the upper surface of a first substrate 6 can also be called upper surface metallization 11. The bare die semiconductor elements and the upper surface metallization 11 can be bonded together, for example, by at least one soldered joint, in particular a silver solder joint, at least one welded joint, by sintering or a comparable process. Such a connection in a materially bonded manner exhibits very good and stable heat transfer.

A heat sink made of metal can dissipate heat very effectively. However, in certain circumstances it can have the disadvantage of being electrically conductive. Because of the electrical conductivity thereof, there is a risk that currents will be induced therein. These can lead to additional unwanted losses. However, the dimensions of the heat sink can be reduced to such an extent due to the particularly high heat dissipation efficiency thereof that the induction of currents can also be significantly reduced.

The bare die layer 14 can have regions where no semiconductor structural elements are arranged. These regions can be filled with a filler material 141. This filling material 141 can be designed to improve stability, reduce mechanical stresses and/or improve electrical insulation, for example by increasing air and/or creepage distances.

The semiconductor devices of the semiconductor structural element 28 mounted on the first substrate 6 have at least one first connection 77 which is thermally and electrically connected to at least one first region of the upper surface metallization 11 of the first substrate 6 facing the semiconductor assembly 28.

An electrically insulating second substrate 18 is attached here to the semiconductor assembly 28, and has a metallization layer 17, 19 on the upper and lower surfaces thereof.

The semiconductor structural elements of the semiconductor assembly 28 have at least one second connection 79 which is thermally and electrically connected to at least one second region of the metallization layer 17 of the second substrate 18 facing the semiconductor assembly 28.

The first substrate 6 can preferably be a ceramic substrate. Examples of suitable ceramic materials include aluminum oxide ceramic, beryllium oxide ceramic, aluminum nitride ceramic, and sapphire. The metallization 11 can be applied to the first substrate 6 using a previously mentioned bonding process, for example by means of direct bonded copper. In this process, a copper foil can be bonded to the substrate, for example the ceramic substrate, under pressure and high temperature. Alternatively, metallization processes such as IMB (insulated metal substrate) or AMB (active metal brazed) can be used. Such a connection in a materially bonded manner exhibits very good and stable heat transfer.

A metallization 9 is also applied to the side of the first substrate 6 facing away from the bare die layer 14. This can be named as the lower surface metallization layer 9. The lower surface metallization 9 can also be applied to the first substrate 6 by means of a bonding process, for example by means of direct bonded copper. The first heat sink 5 is fixedly bonded to the lower surface metallization 9. Such a connection in a materially bonded manner exhibits very good and stable heat transfer.

In the example shown in FIG. 1, the first heat sink 5 is produced using a metal layer bonding process. In this process, individual metal foils 27a-m, preferably copper foils, are structured at least partially by means of laser processing and/or punching and/or manufactured by means of electroplating processes and then joined together. The structuring or manufacturing process is carried out in such a way that, after the layers are joined together, closed first cooling channels 35 are created through which a cooling medium can flow. By means of a cooling channel structure, the coolant can be guided specifically to the locations of the first heat sink 5 that require particularly high temperatures. Preferably, the metal foils are joined together using a bonding process under high pressure and at high temperature. For this purpose, oxide layers can be formed on the surfaces of the copper layers, which are then welded together, wherein the temperature is preferably chosen to be high enough that the oxide layers melt, but not the metal foils. This is how the metal foils combine to form a monolithic heat sink. If the metal foils are made of copper, for example, this is also referred to as direct copper bonding, abbreviated DCB. The metal foils 27a-m preferably have a thickness of 0.4 mm or less, in particular 0.25 mm or less.

There are various options for producing the structure shown in FIG. 1. According to an embodiment, the production of the first substrate 6, provided with metallizations 9 and 11, and the first heat sink 5 each takes place in separate steps. The first heat sink 5 is then fixedly bonded to the metallization 9, for example by means of a bonding process, in particular by means of direct copper bonding. In this way, the lower surface metallization 9 can be part of the heat sink 5, in particular the monolithic heat sink. Other less preferred bonding methods of the heat sink 5 with the metallization can include, for example: soldering, welding, or sintering. According to a second, alternative manufacturing process, all layers, i.e., both the first substrate 6 and the metal foils 27g-m, from which the first heat sink 5 is formed, are bonded together in a bonding process under high pressure and at high temperature, preferably by means of direct copper bonding and direct-bonded copper.

In the same step, the upper surface metallization 11 is also preferably applied to the upper surface of the substrate 6.

The shaping of the metallization 11 into the conductor structures 11a, 11b, 11c can then be carried out, for example, by an etching process.

In the first power electronics component 188 shown in FIG. 1, the upper surface of the bare die layer 14 is also cooled by means of a second heat sink 26. In this way, effective heat dissipation of the bare die layer 14 is enabled from both sides. For this purpose, a second substrate 18 is arranged on the upper surface of the bare die layer 14, which is provided with metallizations 17, 19 on both sides. The bare die layer 14 is fixedly bonded to conductor structures of the metallization 17 of the second substrate 18 and the second substrate 18 is fixedly bonded to the second heat sink 26 via the metallization 19. Just like the first heat sink 5, the second heat sink 26 can also be manufactured from a variety of metal foils 27a-f using a metal layer bonding process. The second heat sink 26 has at least one second cooling channel 37 for dissipating heat from the first power electronics component 188.

Since the layer structure on the upper surface of the bare die layer 14 corresponds to the layer structure on the lower surface of the bare die layer 14, reference is made to the description of the structure attached to the lower surface of the bare die layer 14 with regard to the various possibilities for connecting the layers.

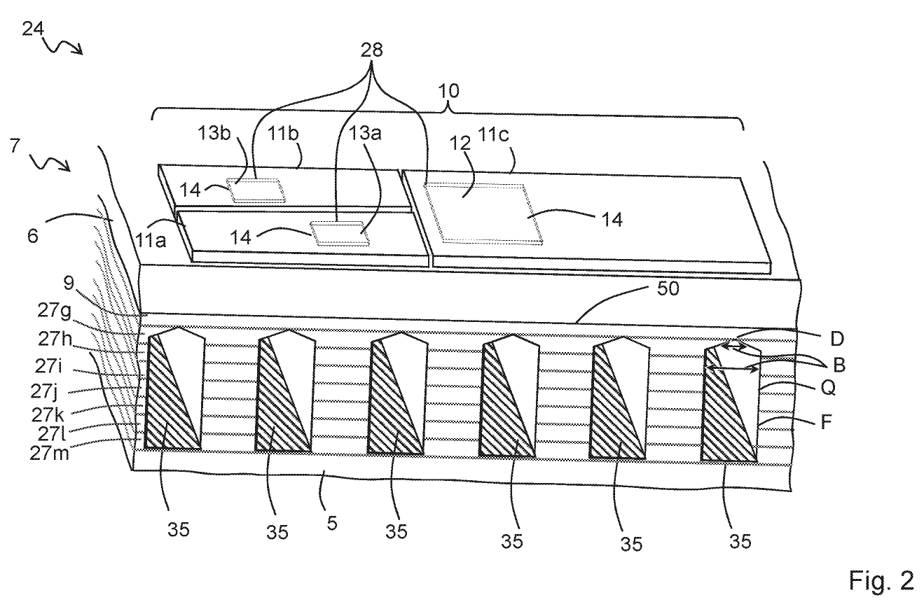

Particularly efficient dissipation of the heat generated by the semiconductor structural elements can be achieved in the first power electronics component 188 shown in FIG. 1 if the cooling channels 35 and 37 are arranged in the immediate vicinity and at a short distance from the respective substrates 6 and 18. For the first heat sink 5, such an embodiment is shown in FIG. 2. For example, "small distance" means a distance of less than 50 μm.

FIG. 1a shows an industrial process assembly 1, preferably a plasma process assembly or a heating assembly. The industrial process assembly 1 comprises:

an electrical power converter 4,

a load 2, preferably a plasma process or heating process, e.g., an induction or microwave heating process, wherein the load 2 is electrically connected to the electrical power converter 4 such that the electrical power converter 4 can supply the load 2 with the required electrical power,

optionally an additional adaptation unit 3 which is connected between the power converter 4 and the load 2.

The power converter 4 comprises:

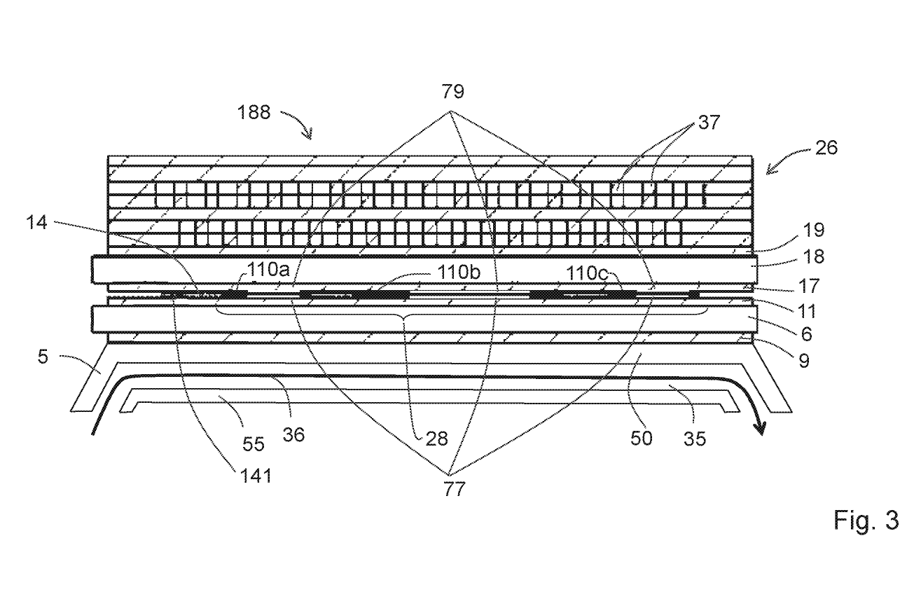

two of the first power electronics components 188, as previously described, for example, in the description of FIG. 1 and subsequently, for example, in the description of FIG. 3,

a cooling unit 22, which, as described above and below, has one or more distribution units 20 and a carrier unit 21,

a circuit board 75,

a unit 10 to be cooled, in particular an electrical unit, preferably a semiconductor assembly, preferably having a power semiconductor structural element,

further electronic members 8a, 8b, 8c, wherein the further electronic members 8a, 8b, 8c and the unit 10 to be cooled are arranged on or at a circuit board 75 and are connected to electrical contacts, wherein the unit 10 to be cooled is fixedly bonded, in particular in a materially bonded manner, to the heat sink 5, 85.

At or on the circuit board 75, two power semiconductor structural elements, in particular transistors S1, S2, are arranged as a unit 10 to be cooled, each having a first and a second power connection and a control connection, wherein both transistors S1, S2 can be connected to a series circuit with one of the power connections thereof. The remaining power connections can be used to supply direct current or direct voltage. A control electronics unit 114 can be connected to the control connections of the power semiconductor structural elements.

On the circuit board 75 is also arranged a power transformer 197, comprising a primary winding 196 and a secondary winding 194. The primary winding 196 and the secondary winding 194 of the power transformer 197 are each designed as planar conductor tracks, which are arranged in different positions on the circuit board 75. The circuit board has a thermal connection with the cooling unit 22.

The thermal connection with the cooling unit 22 can have a thermally conductive compensation layer, which is fixedly bonded with the first surface thereof to the first surface of the circuit board 75, and a bonding layer, which is fixedly bonded with the first surface thereof to the second surface of the thermally conductive compensation layer, and fixedly bonded with the second surface thereof to the heat distributor.

FIG. 2 shows an electronic assembly 24 with a cooling assembly 7 and with an electrical unit 10 to be cooled, which is preferably a semiconductor assembly 28. The electronic assembly 24 can be part of a power electronics component 188, as described above and below. The cooling assembly 7 includes the first heat sink 5 and the first substrate 6 which is connected thereto in a materially bonded manner. The first heat sink 5 has a first cooling channel 35 through which coolant can flow in a specified direction. The first heat sink 5 further comprises a cooling wall 50 on the side of the first cooling channel 35 facing the electrical unit 10 to be cooled. The first substrate 6 is connected in a materially bonded manner to the first heat sink 5 on the cooling wall 50. On the side facing away from the first substrate 6 and the first heat sink 5, the electrical unit 10 is mechanically fixedly bonded to the first substrate 6. The electrical unit 10 comprises:

a conductor structure 11a, 11b11c, collectively referred to as metallization 11,

a semiconductor assembly 28 comprising:

a semiconductor component 12, which can be 3-pin, in particular a transistor, or a PIN diode, e.g., for switching high frequency power between different paths,

further 2-pole semiconductor components to be cooled 13a, 13b, e.g., diodes.

The 3-pin semiconductor device 12 can be designed as a bare die layer 14. This allows for very direct heat coupling. It can be connected in a materially bonded manner and fixedly, e.g., by a soldered connection to the conductor structure 11c. This results in a particularly low and stable thermal resistance.

One or more, in particular all, 2-pole semiconductor devices 13a, 13b to be cooled can be designed as a bare die layer 14. This allows for very direct heat coupling. It can be connected in a materially bonded manner and fixedly, e.g., by a soldered connection to the conductor structure 11c. This results in a particularly low and stable thermal resistance.

The 3-pin semiconductor device 12 and the 2-pin semiconductor devices 13a, 13b are also collectively referred to as semiconductor structural elements.

A metallization 9 is also applied to the side of the first substrate 6 facing away from the bare die layer 14.

The cooling assembly 7 is designed so that during operation the coolant is guided through the first cooling channel 35 at a predetermined operating pressure which is above the ambient pressure which is applied to the first substrate 6 on the side of the electrical unit 10 to be cooled. The distance D between the first cooling channel 35 and the cooling wall 50 is chosen to be so small that the first heat sink 5 cannot ensure sufficient structural stability and/or tightness at the specified operating pressure without being connected in a materially bonded manner to the first substrate 6. The first substrate 6 and the connection thereof in a materially bonded manner with the first heat sink 5 on the cooling wall 50 is designed in such a way that the cooling assembly 7 can ensure this sufficient structural stability and tightness. The first heat sink 5 is monolithic.

In particular, the distance D can be equal to, or less than or equal to the thickness of the metallization 9 and/or less than or equal to 50 µm.

The first cooling channel 35 is characterized in that the cross-section Q thereof has at least in sections a geometric shape F, the width B of which, measured parallel to the cooling wall 50, decreases in the direction of the cooling wall 50. The geometric shape F of the cross-section Q on the cooling wall 50 has at least in sections distance D to the first substrate 6, which is designed to be so small that, at the given operating pressure of the coolant, the first heat sink 5 cannot ensure sufficient structural stability and/or tightness without the first substrate 6 being connected thereto in a materially bonded manner. A typical specified operating pressure can be, for example, 3 bar or more of overpressure relative to ambient pressure.

As an alternative to the production of the heat sinks 5, 26 by means of a metal layer bonding process as illustrated in FIG. 1, at least one of the heat sinks 5, 26 can be produced by means of an additive process, for example by means of selective laser melting. Additive manufacturing processes are characterized by the fact that the structure is gradually applied from the same material. Thus, the material can be melted during application. To produce such a heat sink, for example, the metallization applied to the side of the respective substrate facing away from the bare die layer 14 can be further built up using an additive manufacturing process.

Additive manufacturing processes enable the layer-by-layer construction of members directly from digital models by selectively applying material. In contrast to subtractive methods, where material is removed, additive processes offer high flexibility in the design of complex geometries and are particularly efficient in material consumption. Furthermore, additive manufacturing processes provide for manufacturing monolithic members with cavities that have complex internal structures. These technologies are widely used in prototype development, small-batch production and increasingly also in industrial production.

A heat sink made of metal using an additive manufacturing process has a surface structure unique to this manufacturing process. The structure is characterized by a rough surface, because in the additive manufacturing process the metal is first melted and then hardened by cooling. This roughness is therefore similar to a very fine crystal structure, such as is found in nature. This roughness can lead to a particularly large surface area between the coolant and the metal. This increase in surface area can enhance heat transfer between the heat sink and the coolant. Furthermore, turbulence can form particularly well on the rough surface, which can also have a beneficial effect on the heat transfer between the heat sink and the coolant. The heat sink therefore exhibits this rough surface structure, characteristic of the additive manufacturing process, at least partially, preferably predominantly, on the wall facing the coolant.

One or more outer surfaces of the heat sink can be ground or shaped after the additive manufacturing process step. This allows for advantageous heat transfer to the heat sink from a winding or electrical conductor of the heat-generating member and/or from a core of the heat-generating member.

In an aspect, the heat sink is produced using selective laser melting (SLM). Selective laser melting is an additive manufacturing process used to produce metal members. The metal powder is applied layer by layer and precisely melted and solidified using a high-performance laser to create a three-dimensional member. A heat sink produced from metal using SLM has a surface structure unique to this manufacturing process. The structure is characterized by a particularly rough surface.

SLM is frequently used in industries that place high demands on member quality and precision, such as aerospace, medical technology, automotive engineering and tool production. Thanks to the ability thereof to manufacture members with complex internal structures and high material utilization, the process is increasingly used for demanding, customized applications.

Advantages of SLM processes include the production of complex geometries. The process enables the production of highly complex and delicate structures that are difficult or impossible to create using conventional manufacturing methods. Furthermore, the SLM process allows for a wide variety of materials. SLM can be performed with various metals such as aluminum, titanium, stainless steel, and nickel, as well as numerous alloys with these materials, making it attractive to numerous industries. The SLM process is also very economical for small production runs. Especially in the production of prototypes and small series, SLM can be more economical than conventional manufacturing processes, as no special tools or molds are required. The SLM process using copper was barely developed in the past and was considered particularly expensive.

The disadvantages of the SLM manufacturing process are the duration and the cost. For the same member size, a heat sink produced using an additive manufacturing process, especially an SLM manufacturing process, would be many times more expensive than a heat sink produced by machining, pressing, or casting. In the past, this manufacturing process was therefore discouraged for larger production runs and cost-critical developments. However, since the size of the heat sink can be significantly reduced due to the considerably increased efficiency thereof, costs and manufacturing time can also be reduced. This makes heat sinks produced using additive manufacturing, especially the SLM manufacturing process, interesting again. Furthermore, since this also significantly reduces the weight and dimensions of the heat-generating member, such a heat sink becomes even more interesting. In the course of development, even more heat can be dissipated from a smaller area on the heat-generating member. This made it possible to improve the conductor and/or the core of the heat-generating member, in particular to further reduce the size thereof, which in turn allowed the dimensions of a power converter to be further reduced. Members around the heat-generating member can also be arranged in a more space-saving manner. This also reduced the length of supply lines to these members. This led to a reduction in electromagnetic interference and susceptibility to malfunctions in the device, and to a further reduction in power loss. All these positive effects combined justify the higher production costs of a heat sink produced using additive manufacturing, especially the SLM manufacturing process.

In an aspect, the heat sink comprises a single-piece main body. This means that the heat sink is designed as a single, integrated member. This can enable increased mechanical stability and improved heat dissipation. By avoiding a multi-part construction, potential weak points that can arise from connections or joints can be avoided. This can contribute to the longevity and reliability of the heat-generating member. This is particularly advantageous in connection with the liquid cooling of the heat sink, since the one-piece main body does not require seals or the like, which would be necessary in multi-piece designs. This can reduce the risk of coolant leakage, which can further increase the operational safety and efficiency of the cooling system. This design can also simplify the production and assembly of the heat-generating member if fewer individual parts are required and the heat sink can be manufactured more efficiently as an integral part of the heat-generating member.

FIG. 3 shows an embodiment of the first power electronics component 188, in which the heat dissipation of the semiconductor structural elements on the upper surface is carried out by means of the second heat sink 26, which is manufactured by means of a metal layer bonding process. The first heat sink 5, intended for cooling the lower surface of the semiconductor structural elements, is manufactured in the embodiment of FIG. 3 using an additive manufacturing process. It can be seen that the first heat sink 5 has a first cooling channel 35 through which flows a cooling flow 36. This cooling flow 36 cools the first cooling wall 50, which is fixedly bonded to the metallization 9 attached to the lower surface of the first substrate 6. It is particularly advantageous if the metallization 9 of the first substrate 6, which was applied to the first substrate 6, for example by means of direct bonded copper, is built up to the first heat sink 5 by means of the additive manufacturing process. Alternatively, the first heat sink 5 can also be produced separately using the additive manufacturing process and then fixedly bonded with the metallization 9, for example by soldering, welding, or sintering.

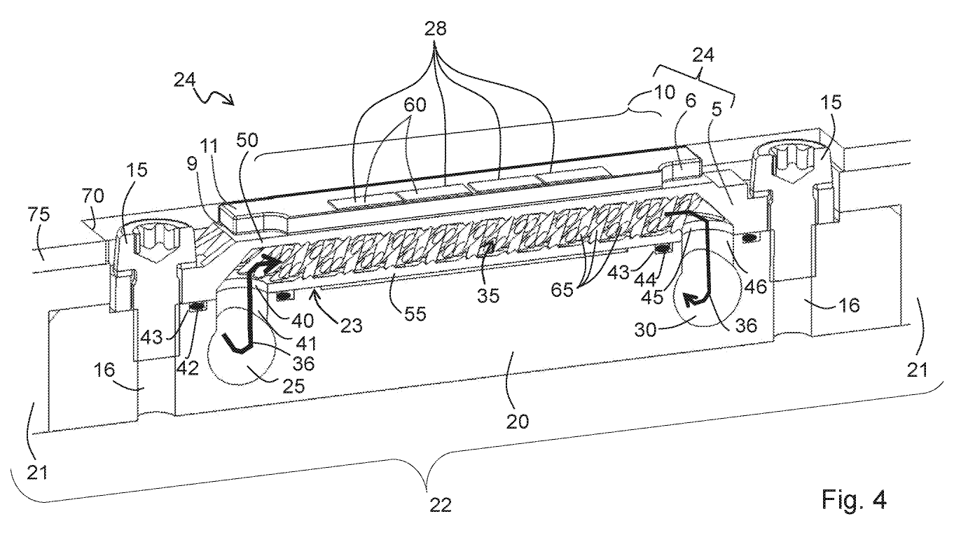

The embodiment shown in FIG. 3 can be designed such that a planar extended bare die layer 14, comprising a plurality of semiconductor structural elements, is cooled on both sides. Alternatively, the heat sink assembly shown in FIG. 3 can also be designed in the form of a microcooler for cooling individual semiconductor structural elements or groups of semiconductor structural elements. One such solution is shown in FIG. 4.

FIG. 4 shows a further embodiment of an electronic assembly 24 as part of a fourth embodiment of a power electronics component 100, 188, 118. The electronics assembly 24 is shown in longitudinal section. The electronics assembly 24 comprises a first heat sink 5 that is configured to cool an electrical unit 10 to be cooled that is mounted on the first heat sink 5. The electrical unit 10 to be cooled can in particular be an electrical unit, preferably a semiconductor assembly 28.

The first heat sink 5 is releasably connected to a cooling unit 22. In the example shown in the figures, the cooling unit 22 comprises a distribution unit 20 designed here, for example, to supply the first heat sink 5 with coolant. Furthermore, the cooling unit 22 comprises a carrier unit 21 into which, for example, the distribution unit 20 is inserted. The cooling unit 22 has a receptacle 23 into which the first heat sink 5 can be releasably inserted. The first heat sink 5 is then secured to the cooling unit 22 by means of at least one securing means 15, preferably by way of one or more screws. The cooling unit 22 has at least one receiving device 16 for the at least one securing means 15. To separate the first heat sink 5 from the cooling unit 22, at least one securing means 15 is first undone. The first heat sink 5, together with the electrical unit 10 to be cooled attached thereto, can then be removed from the receptacle 23 of the cooling unit 22.

In an aspect, the electrical unit 10 is mechanically and thermally connected to the first heat sink 5. The electrical unit 10 can be connected to the first heat sink 5, for example, by way of one or more soldered connections. In an embodiment, the electrical unit 10 can be connected to the first heat sink 5, for example by way of sintering. Alternatively, the electrical unit 10 can be welded to the first heat sink 5. As another, albeit less advantageous, alternative, the electrical unit 10 can also be connected to the first heat sink 5 by way of a layer of thermal paste. aN aspect of the development described here, however, is to make the connection between the electrical unit 10 to be cooled and the first heat sink 5 as thin and using as little additional material as possible. In the course of the considerations, simulations and experiments for this development described here, it became apparent that this is in particular made possible when the heat sink with fluid flowing therethrough is fixedly bonded, in particular in a materially bonded manner, to the electrical unit 10 to be cooled. This can be achieved, for example, by soldering, sintering, pressing, or direct copper bonding (DCB). The term ‘fixedly’ here can mean: ‘only destructively detachable’. i.e., using connecting means that cannot be undone even with tools without destroying either the electrical unit 10 to be cooled or the first heat sink 5, or both components. It was further realized that such a solution will only be feasible if a new solution can be found for the interchangeability of the circuit board component with electronic members and, in particular, with the electrical unit 10 to be cooled is fastened thereto. This is achieved with the first heat sink 5.

The first heat sink 5 and the electrical unit 10 that is mechanically fixedly bonded to the first heat sink 5 together form an electronic assembly 24. This electronic assembly 24 can be inserted into the receptacle 23 of the cooling unit 22 and removed from this receptacle 23.

The cooling unit 22 is designed to supply coolant to the first heat sink 5 attached to the cooling unit 22, and to discharge the coolant again after the coolant has flowed through the first heat sink 5. A first flow channel 25 through which coolant can be supplied to the first heat sink 5 can be seen within the cooling unit 22. A second flow channel 30 through which the coolant can be discharged can be seen within the cooling unit 22. The first heat sink 5 has a first cooling channel 35 through which the coolant can flow. A coolant supply 40 is provided at a first end of the first cooling channel 35 and a coolant discharge 45 is provided at the second end of the first cooling channel 35 opposite the first end. The coolant supply 40 and the coolant discharge 45 are fluidically connected to the first cooling channel 35.

The cooling unit 22 comprises a first fluid port 41 that is fluidically connected to the first flow channel 25, and a second fluid port 46 that is fluidically connected to the second flow channel 30. When the first heat sink 5 is inserted and subsequently secured in the receptacle 23, a first fluidic connection is produced between the first fluid port 41 and the coolant supply 40, as well as a second fluidic connection between the second fluid port 46 and the coolant discharge 45.

To seal the first fluidic connection, a first sealing ring 42 is arranged in a groove 43 between the cooling unit 22 and the first heat sink 5, wherein the sealing ring 42 entirely surrounds the first fluid port 41. A second sealing ring 44 that entirely surrounds the second fluid port 46 is likewise provided at the second fluid port 46 and is arranged in a groove 43 between the cooling unit 22 and the first heat sink 5. When the at least one securing means 15 is secured, for example when the at least one screw is tightened, the first heat sink 5 is pressed against the first fluid port 41, and the first sealing ring 42 is likewise pressed against the second fluid port 46 and the second sealing ring 44. This application of pressure produces a liquid-tight first fluidic connection and a liquid-tight second fluidic connection between the cooling unit 22 and the first heat sink 5.

As shown in FIG. 4, a cooling flow 36 can be produced within the cooling unit 22. The coolant flows from the first flow channel 25 via the first fluid port 41 and the coolant supply 40 into the first cooling channel 35. The coolant flows through the first cooling channel 35 and is discharged again via the coolant discharge 45, the second fluid port 46, and the second flow channel 30.

The first heat sink 5 has a first cooling wall 50 on the side facing the electrical unit 10 to be cooled. On the side of the first heat sink 5 facing away from the electrical unit 10 to be cooled, the first cooling channel 35 is bounded by a second cooling wall 55 that is opposite the first cooling wall 50. Preferably, the second cooling wall 55 is configured to be parallel to the first cooling wall 50.

In the example shown in FIG. 4, the electrical unit 10 comprises a semiconductor assembly 28, which includes, for example, an arrangement of transistors 60, which can in particular be designed as bare die semiconductor structural elements. The heat generated during operation of the transistors 60 is dissipated via the coolant flowing in the first cooling channel 35. To achieve a cooling of the transistors 60 on both sides, a second heat sink can be applied to the upper surface of the transistors 60. This second heat sink can, for example, be a heat sink produced using a metal layer bonding process or a heat sink produced using an additive manufacturing process. Such an arrangement is also provided for one or more PIN diodes, e.g., for switching high frequency power between different paths, or a combination of transistor and diode.

To improve thermal exchange between the coolant flowing through the cooling channel 35 and the first heat sink 5, a plurality of cooling pins 65 that extend into the first cooling channel 35 from the first cooling wall 50 and/or from the second cooling wall 55 can be arranged inside the first cooling channel 35. The cooling pins 65 have coolant flowing therearound and ensure an improved thermal coupling between the first heat sink 5 and the coolant.

It can also be seen in FIG. 4 that the electrical unit 10, together with the first heat sink 5 arranged therebelow, can be arranged within a first recess 70 of a circuit board 75.

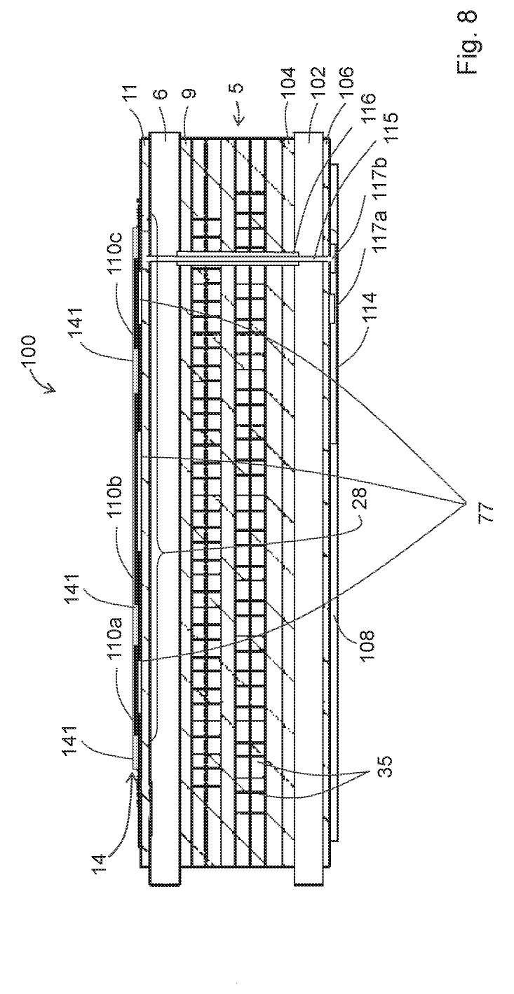

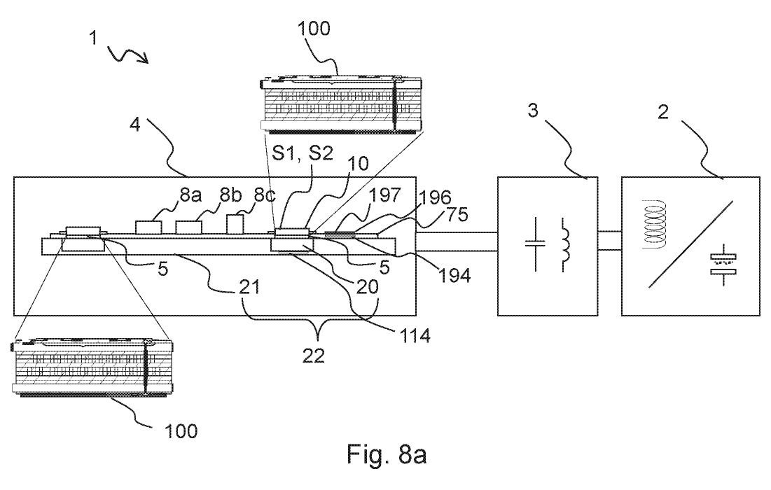

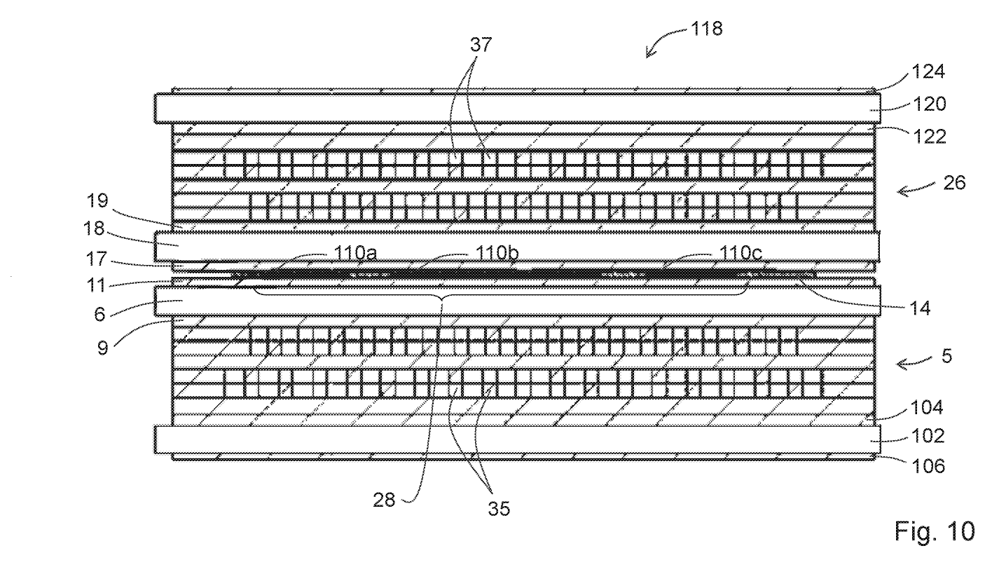

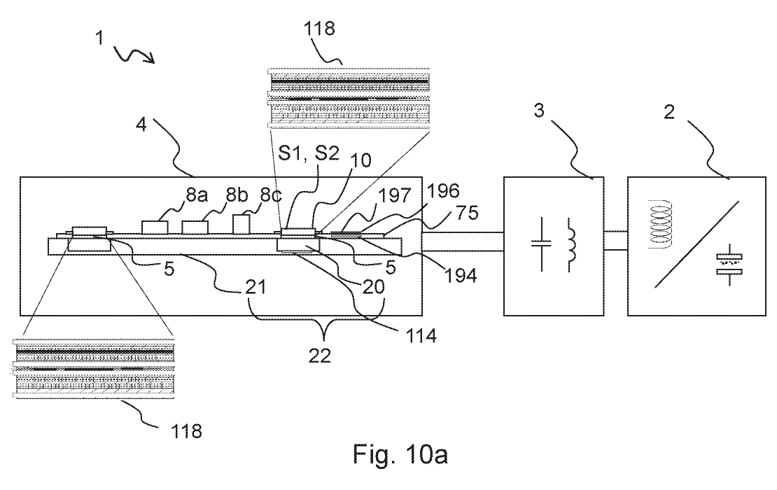

The arrangements shown in FIGS. 1 to 4 can have an electrically insulating additional substrate 102, which has a metallization layer 104, 106 on the upper and lower surfaces thereof, wherein the additional substrate 102 can be attached to the second side of the first heat sink 5 opposite the first side and/or to the second side of the second heat sink 26 opposite the first side. For example, the second side of the first heat sink 5 can be thermally connected to the metallization layer 104 of the additional substrate 102 facing the first heat sink 5. Alternatively or additionally, for example, the second side of the second heat sink 26 can be thermally connected to the metallization layer of the additional substrate facing the second heat sink 26. This can be seen from a comparison of FIGS. 1 to 4 with FIGS. 8 and 10.

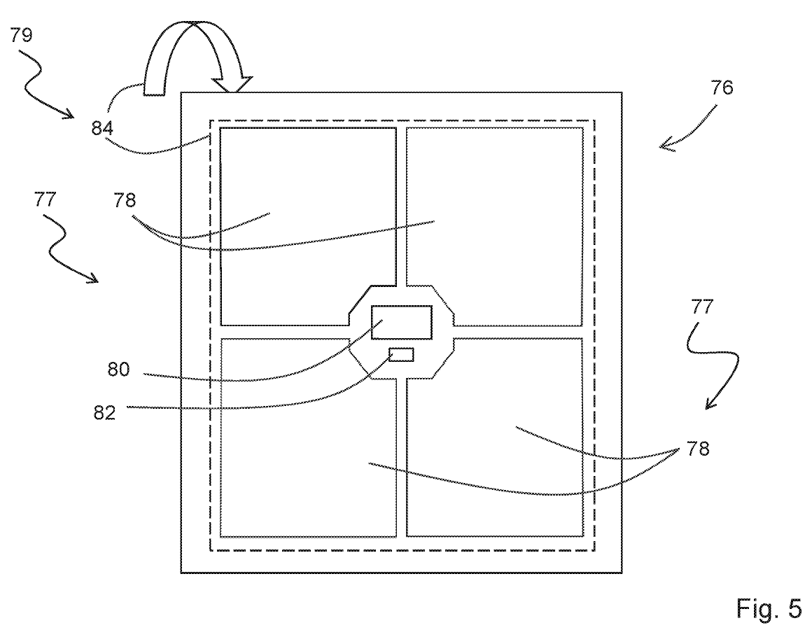

FIG. 5 shows how a bare die structural element, for example designed as an IGBT 76, can be electrically contacted. The IGBT 76 has on the first side thereof first connections 77, in particular designed as four emitter connection surfaces 78, a control connection surface 80 and a test connection surface 82 required for testing purposes. On the rear side, the IGBT 76 has a second connection 79, in particular designed as a collector connection surface 84. These connection surfaces can be electrically contacted by the conductor structures 11a-c of the metallizations 11 and/or 17. In particular, the collector connection surface 84 is also electrically connected directly to the connection of the bare die structural element with the conductor structure 11c. In particular, the emitter connection surfaces 78 are connected to a conductor structure of the opposite metallization 17. This too can take the form of ladder structures, as will be explained in more detail below and with further illustrations.

The arrangement can also be reversed, i.e., the collector connection surface 84 can be directly electrically connected to the connection of the bare die structural element of a conductor structure of the metallization 17, and the emitter connection surfaces 78 can be connected to a conductor structure 11c of the opposite metallization 11.

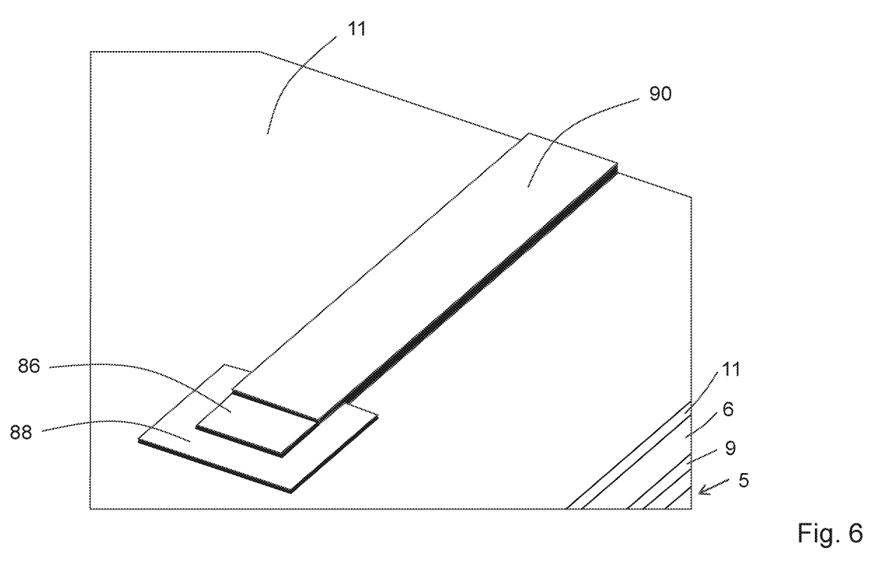

With a cooling of the semiconductor structural elements from both sides, the question arises as to how a control connection of a semiconductor structural element can be guided to the outside. There are different possibilities therefor, which are described below in FIGS. 6 to 8.

FIG. 6 shows the metallization 11, which is applied to the first substrate 6. The metallization 11 can, for example, be made of copper, preferably copper coated with NiAu. The coating can serve as a diffusion barrier. First, an insulating material layer 86 is applied to the metallization 11, extending laterally outwards from the location of the respective control connection. A conductor track layer 88 of conductive material, designed to electrically contact the control connection of the respective semiconductor structural element, is then applied to this insulating material layer 86. The insulating material layer 86 can have a recess at the location of the gate connection. A conductor track insulation material layer 90 is then applied to this conductor track layer 88 of conductive material, which also extends laterally outwards from the location of the control connection. The conductor track layer 88 is thus insulated from the metallization 11 by the insulating material layer 86 and from the bare die layer 14 by the conductor track insulating material layer 90. The control connection can be electrically contacted via the conductor track layer 88 made of conductive material, which is guided to the outside.

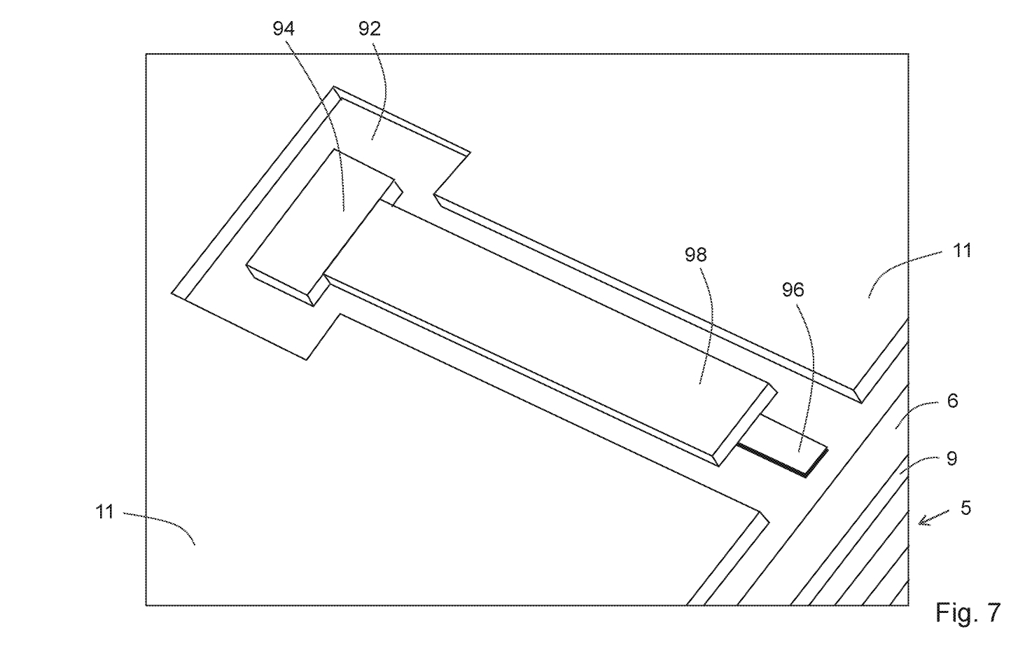

FIG. 7 shows another means of guiding the control connection of the semiconductor structural element laterally to the outside to make electrical contact with the control connection from the side of the power electronics component. FIG. 7 shows the metallization 11 applied to the first substrate 6. In the first step, the metallization 11 within the trench-shaped region 92 is removed up to the first substrate 6, e.g., etched away, wherein an inner region 94 of the metallization 11 is left as is. This inner region 94 extends laterally outwards from the control connection of the semiconductor structural element and is isolated from the rest of the metallization 11 by the trench-shaped region 92 running around the inner region 94. Subsequently, within a sub-region 96 of the inner region 94, etching is carried out to a certain depth, wherein part of the metal is left as a control connection conductor track. Subsequently, a conductor track insulating material layer 98 is deposited onto this partially etched sub-region 96. This conductor track insulating material layer 98 insulates the laterally outward-leading control connection of the semiconductor structural element from the bare die layer 14.

According to another aspect of the development described here, at least one of the heat sinks has an additional substrate arranged on the side of the heat sink facing away from the bare die layer 14, so that the heat sink is arranged in a sandwich structure between two substrates.

FIG. 8 shows a second power electronics component 100 according to the second aspect of the development described here. FIG. 8 shows that the first substrate 6 is arranged below the bare die layer 14, wherein the metallization 11 of the first substrate 6 is connected to the bare die layer 14 as described above. The first heat sink 5 is attached to the side of the first substrate 6 facing away from the bare die layer 14, and an additional substrate 102 is arranged on the side of the first heat sink 5 facing away from the bare die layer 14. The additional substrate 102 has metallizations 104, 106 on both sides. The metallization 104 facing the first heat sink 5 is fixedly bonded to the first heat sink 5. The further metallization 106 is arranged on the side of the substrate 6 facing away from the heat sink 5 and can be designed like a previously described conductor structure for receiving electronic members, in particular semiconductor members. This additional substrate 102 can increase the stability of the heat sink 5. In addition, the further metallization 106 on the side of the substrate 6 facing away from the heat sink 5 provides for arranging drivers and/or measuring electronics with very short electrical paths to the power components of the bare die layer 14.

The first heat sink 5 is therefore arranged in a sandwich structure between the first substrate 6 and the additional substrate 102. The substrates 6 and 102 preferably consist of ceramic, and therefore, as a result of this sandwich structure, an additional mechanical stabilization of the first heat sink 5 is achieved. Another advantage is that one or more semiconductor structural elements, e.g., in a further bare die layer 108, can be arranged on the metallization 106, which is located on the side of the additional substrate 102 facing away from the first heat sink 5. The additional substrate 102 can therefore be used, for example, to accommodate driver and control circuits, e.g., a control electronics unit 114 for the actual power electronics. Electrical connections can be formed between the semiconductor structural elements, e.g., the control electronics unit 114, which can be part of the further bare die layer 108, and the semiconductor structural elements 110a-c of the bare die layer 14 arranged on the first substrate 6, using one or more vias 115 extending through the first heat sink 5. At least one connection 117a of the control electronics unit 114 can be thermally and electrically connected to at least one region of the further metallization layer 106 facing the control electronics unit 114. At least one further connection 117b of the control electronics unit 114 can be electrically connected to a connection 119 of the semiconductor assembly 28 via at least one via 115, which runs through the first heat sink 5, in particular insulated therefrom.

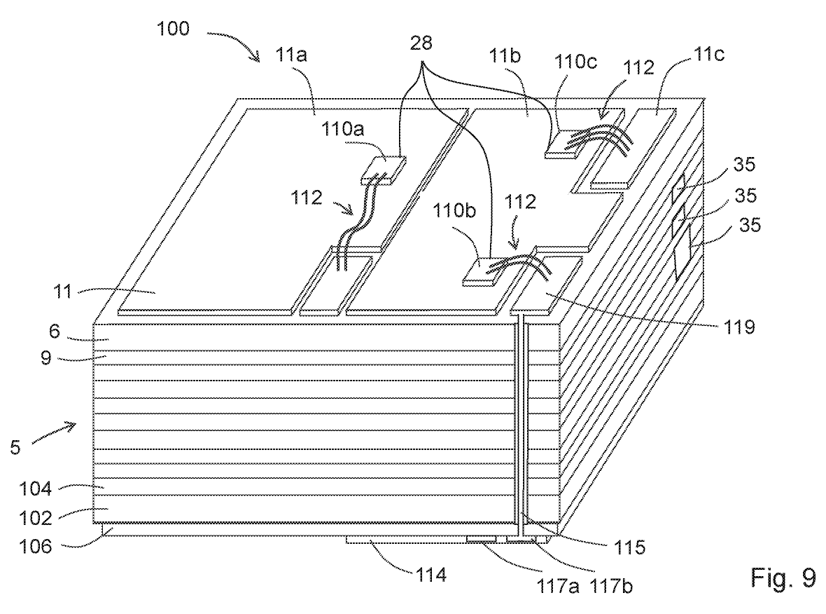

The second power electronics component 100 shown in FIG. 8 is shown again in oblique view in FIG. 9. FIG. 9 shows the first substrate 6 with the metallizations 9 and 11 on both sides, the additional substrate 102 with the two metallizations 104 and 106, and the first heat sink 5 arranged therebetween. Semiconductor structural elements 110a, 110b,110c are attached to the upper surface of the metallization 11, which are part of the bare die layer 14. On the upper surface of the second power electronics component 100, wave-shaped connecting lines 112, in particular designed as bonding wires, can also be seen, which are intended to establish electrical connections between the semiconductor structural elements 110a, 110b, 110c and the conductor structures on the metallization 11 by means of wire bonding.

On the side of the additional substrate 102 facing away from the first heat sink 5, further semiconductor structural elements such as a control electronics unit 114 are arranged on the metallization 106, which can be connected, for example, via a through-connection, also called a “via” 115, to the semiconductor structural elements 110a, 110b, 110c on the upper surface of the second power electronics component 100.

In the region of the heat sink 5 can be provided a via insulation 116, which protects the through-connection from electrical contact with the heat sink 5.

The first cooling channels 35 run inside the first heat sink 5.

The power electronics component 100 shown in FIG. 8 can optionally have a second heat sink 26, as shown, for example, in FIGS. 1 or 10. This second heat sink 26 can be thermally connected to the metallization layer 19 of the second substrate 18 facing away from the semiconductor assembly 28. The second heat sink 26 can have at least one second cooling channel 37 through which coolant can flow.

FIG. 8a shows an industrial process assembly 1, preferably a plasma process assembly or a heating assembly. The industrial process assembly 1 comprises:

an electrical power converter 4,

a load 2, preferably a plasma process or heating process, e.g., an induction or microwave heating process, wherein the load 2 is electrically connected to the electrical power converter 4 such that the electrical power converter 4 can supply the load 2 with the required electrical power,

optionally an additional adaptation unit 3 which is connected between the power converter 4 and the load 2.

The power converter 4 comprises:

two of the second power electronics components 100, as previously described, for example, in the description of FIG. 8 and subsequently, for example, in the description of FIG. 9,

a cooling unit 22, which, as described above and below, has one or more distribution units 20 and a carrier unit 21,

a circuit board 75,

a unit 10 to be cooled, in particular an electrical unit, preferably a semiconductor assembly, preferably having a power semiconductor structural element,

further electronic members 8a, 8b, 8c, wherein the further electronic members 8a, 8b, 8c and the unit 10 to be cooled are arranged on or at a circuit board 75 and are connected to electrical contacts, wherein the unit 10 to be cooled is fixedly bonded, in particular in a materially bonded manner, to the heat sink 5, 85.

At or on the circuit board 75, two power semiconductor structural elements, in particular transistors S1, S2, are arranged as a unit 10 to be cooled, each having a first and a second power connection and a control connection, wherein both transistors S1, S2 can be connected to a series circuit with one of the power connections thereof. The remaining power connections can be used to supply direct current or direct voltage. A control electronics unit 114 can be connected to the control connections of the power semiconductor structural elements.

On the circuit board 75 is also arranged a power transformer 197, comprising a primary winding 196 and a secondary winding 194. The primary winding 196 and the secondary winding 194 of the power transformer 197 are each designed as planar conductor tracks, which are arranged in different positions on the circuit board 75. The circuit board has a thermal connection with the cooling unit 22.

The thermal connection with the cooling unit 22 can have a thermally conductive compensation layer, which is fixedly bonded with the first surface thereof to the first surface of the circuit board 75, and a bonding layer, which is fixedly bonded with the first surface thereof to the second surface of the thermally conductive compensation layer, and fixedly bonded with the second surface thereof to the heat distributor.

FIG. 10 shows a third power electronics component 118 which has a cooling structure of the type shown in FIG. 8 on both the upper and lower surfaces of the bare die layer 14. On the lower surface of the bare die layer 14 are arranged the first substrate 6 with the two metallizations 9 and 11, the heat sink and the additional substrate 102 with the two metallizations 104 and 106. On the upper surface of the bare die layer 14 are arranged the second substrate 18 with the metallizations 17 and 19, the second heat sink 26, and the additional substrate 120 with the metallizations 122 and 124. The first heat sink 5 has first cooling channels 35 and the second heat sink 26 has second cooling channels 37 through which coolant can flow.

FIG. 10a shows an industrial process assembly 1, preferably a plasma process assembly or a heating assembly. The industrial process assembly 1 comprises:

an electrical power converter 4,

a load 2, preferably a plasma process or heating process, e.g., an induction or microwave heating process, wherein the load 2 is electrically connected to the electrical power converter 4 such that the electrical power converter 4 can supply the load 2 with the required electrical power,

optionally an additional adaptation unit 3 which is connected between the power converter 4 and the load 2.

The power converter 4 comprises:

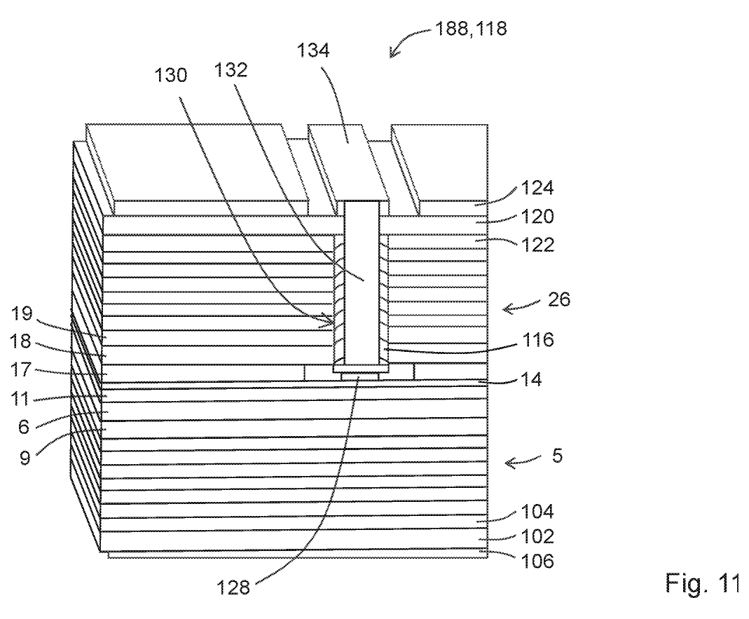

two of the first power electronics components 118, as previously described, for example, in the description of FIG. 10 and subsequently, for example, in the description of FIG. 11,

a cooling unit 22, which, as described above and below, has one or more distribution units 20 and a carrier unit 21,

a circuit board 75,

a unit 10 to be cooled, in particular an electrical unit, preferably a semiconductor assembly, preferably having a power semiconductor structural element,

further electronic members 8a, 8b, 8c, wherein the further electronic members 8a, 8b, 8c and the unit 10 to be cooled are arranged on or at a circuit board 75 and are connected to electrical contacts, wherein the unit 10 to be cooled is fixedly bonded, in particular in a materially bonded manner, to the heat sink 5, 85.

At or on the circuit board 75, two power semiconductor structural elements, in particular transistors S1, S2, are arranged as a unit 10 to be cooled, each having a first and a second power connection and a control connection, wherein both transistors S1, S2 can be connected to a series circuit with one of the power connections thereof. The remaining power connections can be used to supply direct current or direct voltage. A control electronics unit 114 can be connected to the control connections of the power semiconductor structural elements.

On the circuit board 75 is also arranged a power transformer 197, comprising a primary winding 196 and a secondary winding 194. The primary winding 196 and the secondary winding 194 of the power transformer 197 are each designed as planar conductor tracks, which are arranged in different positions on the circuit board 75. The circuit board has a thermal connection with the cooling unit 22.

The thermal connection with the cooling unit 22 can have a thermally conductive compensation layer, which is fixedly bonded with the first surface thereof to the first surface of the circuit board 75, and a bonding layer, which is fixedly bonded with the first surface thereof to the second surface of the thermally conductive compensation layer, and fixedly bonded with the second surface thereof to the heat distributor.

FIG. 11 shows another means by which a control connection 128 of a semiconductor structural element can be contacted from the outside in a third power electronics component 188, 118 with cooling of the semiconductor structural elements on both sides. In the embodiment shown in FIG. 11, the control connection 128 of the semiconductor structural element is electrically contacted from the upper surface of the third power electronics component 118. The bare die layer 14 can be seen in FIG. 11. The first substrate 6 with the two metallizations 9 and 11 thereof and the first heat sink 5 are arranged on the lower surface of the bare die layer 14. The second substrate 18 with the metallizations 17 and 19 thereof and the second heat sink 26 are attached to the upper surface of the bare die layer 14. In addition, in FIG. 11 the additional substrate 102 is attached to the lower surface of the first heat sink 5, which is provided on both sides with metallizations 104, 106. The additional substrate 120, which has the metallizations 122 and 124, is arranged on the upper surface of the second heat sink 26.

For electrical contacting of the control connection 128 is provided a hole 130, which extends from the upper surface of the third power electronics component 118 through the second heat sink 26 to the control connection 128. A pin 132 made of conductive material, preferably copper or another metal, is inserted into the hole 130 such that the pin 130 electrically contacts the control connection 128. In this way, a via is formed that leads the control connection 128 through the second heat sink 26 to the outside. Optionally, a connection surface 134 can be provided on the upper surface of the power electronics component above the additional substrate 120, wherein the connection surface 134 is electrically connected to the control connection 128 via the pin 132.

In the region of the second heat sink 26 can be provided a via insulation 116, which protects the through-connection from electrical contact with the second heat sink 26.

The features disclosed in the above description and the drawings can be important both individually and in any combination for implementing the various configurations of the development described herein.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the

foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A power electronics component, comprising:
an electrically insulating first substrate which has an upper surface, a lower surface an upper surface metallization layer on the upper surface, and a lower surface metallization layer on the lower surface;
a semiconductor assembly mounted on the first electrically insulating substrate which has at least one first connection thermally and electrically connected to at least one first region of the upper surface metallization layer of the first electrically insulating substrate facing the semiconductor assembly;
a first heat sink, a first side of the first heat sink facing the first electrically insulating substrate being thermally connected to the lower surface metallization layer of the first electrically insulating substrate, the lower surface metallization layer of the first electrically insulating substrate facing away from the semiconductor assembly
an additional electrically insulating substrate having an upper surface, a lower surface, an upper surface metallization layer on the upper surface of the additional electrically insulating substrate, and a lower surface metallization layer on the lower surface of the additional electrically insulating substrate, the additional electrically insulating substrate being attached to a second side of the first heat sink opposite the first side, and the second side of the first heat sink being thermally connected to the upper surface metallization layer of the additional electrically insulating substrate facing the first heat sink.

2. The power electronics component according to claim 1, further comprising a control electronics unit arranged on a side of the additional electrically insulating substrate facing away from the first heat sink, wherein at least one connection of the control electronics unit is thermally and electrically connected to at least one region of the lower surface metallization layer of the additional electrically insulating substrate facing the control electronics unit.

3. The power electronics component according to claim 2, wherein at least one further connection of the control electronics unit is electrically connected to a connection of the semiconductor assembly by at least one via that passes through the first heat sink.

4. The power electronics component according to claim 1, wherein the first electrically insulating substrate and/or the additional electrically insulating substrate is one of the following: ceramic substrate, direct bonded copper, insulated metal substrate, active metal brazed, thick film substrate.

5. The power electronics component according to claim 1, further comprising:
a second electrically insulating substrate mounted on the semiconductor assembly, the second electrically insulating substrate having an upper surface, a lower surface, an upper surface metallization layer on the upper surface of the second electrically insulating substrate, and a lower surface metallization layer on the lower surface of the second electrically insulating substrate, wherein the semiconductor assembly has at least one second connection thermally and electrically connected to at least one second region of the lower surface metallization layer of the second electrically insulating substrate facing the semiconductor assembly;
a first cooling channel arranged in the first heat sink; and
a second heat sink thermally connected to the upper surface metallization layer of the second electrically insulating substrate facing away from the semiconductor assembly, wherein the second heat sink has at least one second cooling channel through which coolant is configured to flow.

6. The power electronics component according to claim 5, wherein the second heat sink is at least partially in a form of a layered structure made of thermally bonded metal foils.

7. The power electronics component according to claim 1, wherein the first electrically insulating substrate and/or the second electrically insulating substrate is one of the following: ceramic substrate, direct bonded copper, insulated metal substrate, active metal brazed, or thick film substrate.

8. The power electronics component according to claim 1, wherein the semiconductor assembly has a bare die layer, wherein the bare die layer comprises one or more semiconductor structural elements.

9. The power electronics component according to claim 1, wherein the first heat sink is at least partially in a form of a layered structure made of thermally bonded metal foils.

10. The power electronics component according to claim 9, wherein the first heat sink has at least one first cooling channel through which coolant is configured to flow, wherein the at least one first cooling channel is in a form of at least one recess provided in the thermally bonded metal foils of the first heat sink.

11. The power electronics component according to claim 1, wherein the first heat sink is formed at least partially by additive manufacturing.

12. The power electronics component according to claim 10, wherein the first heat sink comprises a coolant supply and a coolant discharge, both the coolant supply and the coolant discharge being fluidically connected to a first cooling channel of the first heat sink, wherein the first heat sink is configured such that the first heat sink can be detachably attached to a cooler comprising a first fluid port and a second fluid port, and wherein, based on the first heat sink being attached to the cooler, a first fluidic connection is configured to be formed between the coolant supply of the first heat sink and the first fluid port of the cooler and a second fluidic connection is configured to be formed between the coolant discharge of the first heat sink and the second fluid port of the cooler.

13. The power electronics component according to claim 1, wherein the first electrically insulating substrate is materially bonded to the first heat sink on a first cooling wall, wherein the power electronics component is configured such that, during operation, coolant is guided through the first cooling channel at a predetermined operating pressure, wherein a distance between the first cooling channel and the first cooling wall is such that the first heat sink cannot provide sufficient structural stability and/or tightness at the predetermined operating pressure without being materially bonded manner to the first electrically insulating substrate, and
wherein the first electrically insulating substrate and the material bond of the first electrically insulating substrate with the first heat sink on the first cooling wall is configured such that the power electronics component provides sufficient structural stability and tightness at the predetermined operating pressure.

14. The power electronics component according to claim 1, wherein at least one control connection and at least one first power connection are arranged on a first side of the semiconductor assembly and at least one second power connection is arranged on a second side of the semiconductor assembly.

15. The power electronics component according to claim 1, wherein the upper surface metallization layer of the first electrically insulating substrate facing the first side of the semiconductor assembly has at least one first metallization region for electrically contacting at least one control connection of the semiconductor assembly and at least one second metallization region for electrically contacting at least one first power connection of the semiconductor assembly, wherein the at least one first metallization region and the at least one second metallization region are electrically separated from each other, and wherein the at least one first metallization region is guided to a side of the power electronics component and is configured to be electrically contacted from the side of the power electronics component.

16. The component according to claim 14, wherein electrical contacting of the at least one control connection of the semiconductor assembly is provided by at least one via passing through the first heat sink.

17. A method for joining a power electronics component, the method comprising:
arranging a semiconductor assembly on a first electrically insulating substrate which has an upper surface, a lower surface, an upper surface metallization layer on the upper surface of the first electrically insulating substrate, and a lower surface metallization layer on the lower surface of the first electrically insulating substrate;
establishing at least one thermal and electrical connection between at least one connection of the semiconductor assembly and at least one first region of the upper surface metallization layer of the first electrically insulating substrate facing the semiconductor assembly;
arranging a first heat sink on the first electrically insulating substrate;
establishing a thermal and electrical connection between a first side of the first heat sink facing the first electrically insulating substrate and the lower surface metallization layer of the first electrically insulating substrate facing away from the semiconductor assembly;
arranging an additional electrically insulating substrate on a second side of the first heat sink opposite the first side of the first heat sink, the additional electrically insulating substrate having an upper surface, a lower surface, an upper surface metallization layer on the upper surface of the additional electrically insulating substrate, and a lower surface metallization layer on the lower surface of the additional electrically insulating substrate; and
establishing a thermal and electrical connection between the second side of the first heat sink and the upper surface metallization layer of the additional electrically insulating substrate facing the first heat sink.

18. The method according to claim 17, wherein the first heat sink is produced at least partially by a direct copper bonding process.

19. The method according to claim 18, wherein the upper and lower surface metallization layers of the first electrically insulating substrate and metal foils of the first heat sink are bonded in a bonding process.

20. The method according to claim 17, further comprising:
arranging a second electrically insulating substrate on the semiconductor assembly, the second electrically insulating substrate having an upper surface, a lower surface, an upper surface metallization layer on the upper surface of the second electrically insulating substrate, and a lower surface metallization layer on the lower surface of the second electrically insulating substrate;
establishing at least one thermal and electrical connection between at least one second connection of the semiconductor assembly and at least one second region of the lower surface metallization layer of the second electrically insulating substrate facing the semiconductor assembly;
while placing the first heat sink on the first substrate, providing at least one first cooling channel through which coolant is configured to flow;
arranging a second heat sink on the second electrically insulating substrate, wherein the second heat sink has at least one second cooling channel through which coolant is configured to flow; and
establishing a thermal and electrical connection between the second heat sink and the upper surface metallization layer of the second electrically insulating substrate facing away from the semiconductor assembly.

21. The method according to claim 20, wherein the second heat sink is produced at least partially by a direct copper bonding process.

22. The method according to claim 21, wherein the upper and lower metallization layers of the second electrically insulating substrate and metal foils of the second heat sink are bonded in a bonding process.

23. An electrical power converter for an industrial process assembly, comprising:
the power electronics component according to claim 1, wherein the power electronics component is configured to generate a high frequency output power.

24. The electrical power converter according to claim 23, wherein the power electronics component comprises:
two power transistors, each having a first and a second power connection and a control connection, wherein both transistors, are connected in series at one of the respective first and second power connections thereof, wherein a direct current or direct current voltage is connected to remaining power connections of the first and second power connections of the two transistors, wherein a control electronics unit is connected to the control connections of the two transistors, and wherein the control electronics unit is configured to control the two transistors such that they generate high frequency power and switch from a first conducting state to a second conducting state, the conductivity of the first and second conducting states being different.

25. The electrical power converter according to claim 24, wherein the two transistors, are each connected with the respective first power connections thereof to a common ground connection point, wherein the transistors, are of a same design and are arranged on a multilayer printed circuit board.

26. The electrical power converter according to claim 24, wherein one of the two transistors is connected with its first power connection to the other transistor with the second power connection thereof at a common connection point, and wherein the transistors are of a same design and are arranged on the multilayer printed circuit board.

27. The electrical power converter according to claim 24, wherein a power transformer with a primary winding and a secondary winding is arranged on a printed circuit board, wherein the primary winding is connected to at least one of the first and second power connections of the transistors, wherein the primary winding and the secondary winding of the power transformer are each configured as planar conductor tracks arranged in different positions on the printed circuit board, and wherein the printed circuit board has a thermal connection with a cooler.

28. The electrical power converter according to claim 27, wherein the thermal connection with the cooler has a thermally conductive compensation layer fixedly bonded with a first surface thereof to a first surface of the printed circuit board, and a bonding layer fixedly bonded with the first surface thereof to a second surface of the thermally conductive compensation layer and fixedly bonded with a second surface thereof to a heat distributor.
